(19) United States
(12) Patent Application Publication
(10) Pub. No.: US 2024/0150650 A1
(43) Pub. Date: May 9, 2024

(54) QUANTUM-DOT-CONTAINING FILM, LIGHT-EMITTING ELEMENT, WAVELENGTH CONVERSION MEMBER, AND DISPLAY DEVICE

(71) Applicant: SHARP KABUSHIKI KAISHA, Sakai City, Osaka (JP)

(72) Inventor: Yuma YAGUCHI, Sakai City, Osaka (JP)

(21) Appl. No.: 18/280,645

(22) PCT Filed: Mar. 9, 2021
(86) PCT No.: PCT/JP2021/009192

§ 371 Date: Sep. 6, 2023

(51) Int. Cl. C09K 11/88; C09K 11/02; H10K 50/14; H10K 85/60

(52) U.S. Cl. CPC C09K 11/883; C09K 11/02; H10K 50/14; H10K 85/60

(57) ABSTRACT

A quantum-dot-containing film-H includes: a plurality of QDs; and a ligand, wherein the ligand is a monomer that has: at least two coordinating functional groups of at least one species; and at least one polar bonding group of at least one species at a site other than a site at which the ligand is coordinated to the plurality of QDs.

### TECHNICAL FIELD

The present disclosure relates to a quantum-dot-containing film and also to a light-emitting element, a wavelength conversion member, and a display device each including the quantum-dot-containing film.

### BACKGROUND ART

Quantum-dot-containing films containing quantum dots have been suitably used as, for example, a light-emitting layer in a light-emitting element and a wavelength conversion layer in a wavelength conversion member in display devices.

For instance, a light-emitting layer in a light-emitting element is formed by applying and drying a quantum-dot-dispersed solution (colloidal solution) containing quantum dots on, for example, a carrier transport layer such as a hole transport layer or an electron transport layer (see, for example, Patent Literature 1).

When a quantum-dot-containing film is formed in this manner by a solution technique, ligands are commonly used that are coordinated to the surface of quantum dots to improve the dispersibility of the quantum dots in the quantum-dot-dispersed solution.

These ligands are known monofunctional non-polar ligands with a single coordinating functional group coordinated to a quantum dot and are generally non-polar ligands that have no polar bonds.

For instance, Patent Literature 1 discloses forming a light-emitting layer using a quantum-dot-dispersed solution containing ligands such as dodecanethiol or octanethiol.

### CITATION LIST

### Patent Literature

Patent Literature 1: Japanese Unexamined Patent Application Publication, Tokukai, No. 2019-114668

### SUMMARY

### Technical Problem

However, such quantum-dot-containing films containing quantum dots to which ligands are coordinated are hydrophobic.

Patent Literature 1 discloses, as an example, forming an electron transport layer by applying and drying an isopropanol dispersion solution of zinc oxide on a light-emitting layer formed using a quantum-dot-dispersed solution containing dodecanethiol as ligands.

However, if, for example, a solution dissolving an electron transport material in a polar solvent like an isopropanol dispersion solution of zinc oxide is applied on the quantum-dot-containing film, the solution could form such a large contact angle with the quantum-dot-containing film that the solution may disadvantageously be repelled. Consequently, adjoining layers, including the electron transport layer described above, may not be properly staked on the quantum-dot-containing film, which in turn could lead to the formation of a gap at the interface between the quantum-dot-containing film and the adjoining layer.

In addition, as described above, the quantum-dot-containing film is suitably used as a light-emitting layer in a light-emitting element and a wavelength conversion layer in a wavelength conversion member in a display device. For example, Patent Literature 1 also describes use of light-emitting elements in, for example, flat panel display devices and lighting devices.

When the quantum-dot-containing film is used in, for example, a display device in this manner, the quantum-dot-containing film is patterned, for example, for each pixel that emits light of a different color. When the quantum-dot-containing film is patterned in this manner by, for example, photolithography, the quantum-dot-containing film is washed in an organic solvent such as a polar solvent or a non-polar solvent after being patterned. For this reason, the quantum-dot-containing film is required to have solution resistance to polar and non-polar solvents.

The present disclosure, in an aspect thereof, has been made in view of these problems and has an object to provide a quantum-dot-containing film that has high wettability to a polar solvent and also to provide a light-emitting element, a wavelength conversion member, and a display device each including such a quantum-dot-containing film. In addition, the present disclosure, in an aspect thereof, has another object to provide a quantum-dot-containing film that has high solution resistance to polar and non-polar solvents and also to provide a light-emitting element, a wavelength conversion member, and a display device each including such a quantum-dot-containing film.

### Solution to Problem

To achieve these objects, the present disclosure, in an aspect thereof, is directed to a quantum-dot-containing film including: a plurality of quantum dots; and a ligand, wherein the ligand is a monomer that has: at least two coordinating functional groups of at least one species; and at least one polar bonding group of at least one species at a site other than a site at which the ligand is coordinated to the plurality of quantum dots.

In addition, to achieve the objects, the present disclosure, in one aspect thereof, is directed to a light-emitting element including: a first electrode; a second electrode; and a light-emitting layer between the first electrode and the second electrode, wherein the light-emitting layer is the quantum-dot-containing film of an aspect of the present disclosure.

In addition, to achieve the objects, the present disclosure, in one aspect thereof, is directed to a display device including the light-emitting element of an aspect of the present disclosure.

In addition, to achieve the objects, the present disclosure, in one aspect thereof, is directed to a wavelength conversion member including the quantum-dot-containing film of an aspect of the present disclosure as a wavelength conversion layer.

In addition, to achieve the objects, the present disclosure, in one aspect thereof, is directed to a display device including the wavelength conversion member of an aspect of the present disclosure.

### Advantageous Effects of Disclosure

The present disclosure, in an aspect thereof, is capable of providing a quantum-dot-containing film that has high wettability to a polar solvent and high solution resistance to polar and non-polar solvents and also providing a light-emitting element, a wavelength conversion member, and a display device each including such a quantum-dot-containing film.

### BRIEF DESCRIPTION OF DRAWINGS

FIG. 1 is a schematic illustration of a structure of a quantum-dot-containing film in accordance with Embodiment 1.

FIG. 2 is a flow chart representing an exemplary method of forming a quantum-dot-containing film in accordance with Embodiment 1.

FIG. 3 is a drawing illustrating the wettability of quantum-dot-containing films formed in accordance with Example 1 of Embodiment 1, Comparative Example 1, and Comparative Example 2 immediately after the films are formed and the wettability of quantum-dot-containing films formed in accordance with Example 1 of Embodiment 1 and Comparative Example 2 after the films are washed in toluene.

FIG. 4 is a graph representing a relationship between the thickness and the number of washings of quantum-dot-containing films in accordance with Example 2 of Embodiment 1 and Comparative Example 3 after the films are washed in toluene.

FIG. 5 is a graph representing a relationship between the optical absorbency to light with a 450-nm wavelength and the number of washings of quantum-dot-containing films in accordance with Example 2 of Embodiment 1 and Comparative Example 3 after the films are washed in toluene.

FIG. 6 is a graph representing a relationship between the light-emission intensity to light with a 450-nm wavelength and the number of washings of quantum-dot-containing films in accordance with Example 2 of Embodiment 1 and Comparative Example 3 after the films are washed in toluene.

FIG. 7 is a graph representing the thickness of quantum-dot-containing films in accordance with Example 3 of Embodiment 1 and Comparative Example 4 before and after the films are washed in ethanol.

FIG. 8 is a schematic cross-sectional view of an exemplary structure of a major part of a display device in accordance with Embodiment 2.

FIG. 9 is a schematic illustration of an exemplary light-emitting element in accordance with Embodiment 2.

FIG. 10 is a schematic illustration of an exemplary structure of a major part of a display device in accordance with Embodiment 3.

### DESCRIPTION OF EMBODIMENTS

### Embodiment 1

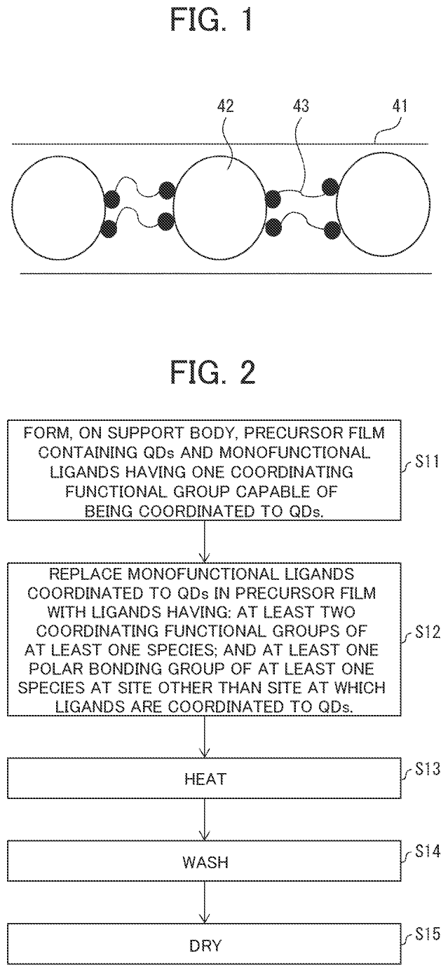

The following will describe an embodiment of the present disclosure with reference to FIGS. 1 to 7. Note that throughout the following description, the language, “A to B,” where A and B are both numerical values, refers to “greater than or equal to A and less than or equal to B” unless otherwise mentioned.

### Quantum-Dot-Containing Film

FIG. 1 is a schematic illustration of a structure of a quantum-dot-containing film 41 in accordance with the present embodiment (hereinafter, a “quantum dot” will be referred to as a “QD”).

Referring to FIG. 1, the QD-containing film 41 in accordance with the present embodiment includes a plurality of QDs 42 and ligands 43.

The QDs 42 are a light-emitting material that emits light (e.g., fluorescent light or phosphorescent light) when excited by excitons. The QDs 42 are not limited in any particular manner and may be any publicly known QDs. Note that QDs are alternatively referred to as semiconductor nanoparticles. The QDs 42 are, for example, a QD fluorescent material.

The QDs 42 may contain, for example, a semiconductor material containing at least one element selected from the group consisting of Cd (cadmium), S (sulfur), Te (tellurium), Se (selenium), Zn (zinc), In (indium), N (nitrogen), P (phosphorus), As (arsenic), Sb (antimony), Al (aluminum), Ga (gallium), Pb (lead), Si (silicon), Ge (germanium), and Mg (magnesium). Note that typical QDs contain Zn. Therefore, the QDs 42 may be, for example, a semiconductor material containing Zn atoms.

In addition, the QDs 42 may have a two-component core structure, a three-component core structure, a four-component core structure, a core-shell structure, or a core-multishell structure. In addition, the QDs 42 may contain doped nanoparticles and may have a structure with a composition gradient where the composition changes in steps. In the present embodiment, as an example, the QDs 42 have, for example, a core-shell structure where the QDs 42 have a core and a shell. For example, the core may be a nanosized crystal of the semiconductor material described above. The shell is provided outside the core so as to cover the core.

As an example, the core has a particle diameter (diameter) of, for example, approximately 1 to 10 nm. The QD 42, including a shell, has an outermost particle diameter of, for example, approximately 1 to 15 nm and preferably approximately 3 to 15 nm.

Note that when the QDs 42 have a core-shell structure, the QDs 42 emit light with a wavelength that is proportional to the particle diameter of the core and that does not change with the outermost particle diameter (including the shell) of the QDs 42. In addition, in the present embodiment, the “particle diameter” refers to the “number-average particle diameter” unless otherwise mentioned.

The ligands 43 are a surface-modification agent that modifies the surface of the QDs 42 by being coordinated to the surface of the QDs 42 with the QDs 42 being receptors. In the present embodiment, the ligands 43 are a monomer that is a compound with a molecular weight of less than or equal to 1,000. Note that the molecular structure of the ligands in the QD-containing film 41 (specifically, the molecular structure of the ligands 43) can be determined with high precision through mass spectrometry of the QD-containing film 41 by, for example, TOF-SIMS (time of flight-secondary ion mass spectrometry). The ligands 43 are a monomer with at least two coordinating functional groups of at least one species for coordination to the QDs 42 and coordinated to, for example, the plurality of QDs 42 as shown in FIG. 1.

The coordinating functional groups are not limited in any particular manner so long as the coordinating functional groups can be coordinated to the QDs 42 and may be, for example, at least one species selected from the group consisting of thiol (—SH) groups, amino (—NR₂) groups, carboxyl (—C(═O)OH) groups, phosphonic (—P(═O)(OR)₂) groups, phosphine (—PR₂) groups, and phosphine oxide (—P(═O)R₂) groups. Note that each R group may independently be a hydrogen atom or any organic group such as an alkyl group or an aryl group. The amino groups may be primary, secondary, or tertiary and are preferably primary amino (—NH₂) groups. In addition, the phosphonic groups, the phosphine groups, and the phosphine oxide groups may also be primary, secondary, or tertiary and are particularly preferably tertiary phosphonic (—P(═O)(OR)₂) groups, tertiary phosphine (—PR₂) groups, and tertiary phosphine oxide (—P(═O)R₂) groups respectively, where the R group is an alkyl group. Note that the alkyl group in these tertiary phosphonic groups, tertiary phosphine groups, and tertiary phosphine oxide groups may be, for example, a C₁-C₂₀ alkyl group.

As described earlier, typical QDs contain Zn. For example, as described in a specific example detailed later, typical QDs contain Zn in the shell (outermost surface). Thiol groups are more likely to be coordinated to Zn-containing nanoparticles than are amino groups, carboxyl groups, phosphonic groups, phosphine groups, and phosphine oxide groups. Therefore, the ligand 43 preferably contains a thiol group as the coordinating functional group, and more preferably, all the coordinating functional groups in the ligand 43 are thiol groups.

In addition, the ligand 43 contains at least one polar bonding group of at least one species at a site in a structural unit thereof other than the site at which the ligand 43 is coordinated to the QD 42 (i.e., in a part other than the coordinating functional groups).

The polar bonding group is not limited in any particular manner so long as the polar bonding group can impart polarity to the ligand 43 (i.e., the polar bonding group can impart bias in the charge distribution in the bonding to the ligand 43) and may be, for example, at least one species of bonding group selected from the group consisting of ether bonding (—O—) groups, sulfide bonding groups (—S—), imine bonding (—NH—) groups, ester bonding (—C(═O)O—) groups, amide bonding (—C(═O)NR′—) groups, and carbonyl (—C(═O)—) groups. Note that this R′ group is a hydrogen atom or any organic group such as an alkyl group or an aryl group.

In addition, if the distance between the QDs 42 that are adjacent across the ligand 43 (i.e., the distance between the QDs 42 that are bonded by the ligand 43) is too short, the QDs 42 can be deactivated. Therefore, the ligands 43 are preferably a monomer containing, as a spacer (spacer group) at a site other than the site at which the ligands 43 are coordinated to the QDs 42 (in a part other than the coordinating functional groups), either a substituted or unsubstituted alkylene group or a substituted or unsubstituted unsaturated hydrocarbon group that bonds to the coordinating functional groups and that are positioned between the coordinating functional groups. Therefore, the polar bonding group preferably bonds to either a substituted or unsubstituted alkylene group or a substituted or unsubstituted unsaturated hydrocarbon group that bonds to the coordinating functional groups.

Note that here, the substituted or unsubstituted alkylene group may or may not have a substituent. Similarly, the substituted or unsubstituted unsaturated hydrocarbon group may or may not have a substituent. In addition, here, “may have a substituent” refers to both cases where a hydrogen atom (—H) is replaced by a monovalent group and cases where a methylene group (—CH₂—) is replaced by a divalent group.

The alkylene group may have either a straight-chain structure or a cyclic structure. In addition, the unsaturated hydrocarbon group may be either an aliphatic hydrocarbon group or an aromatic hydrocarbon group.

The substituent may be, for example, an aliphatic hydrocarbon group, an aromatic hydrocarbon group, an aromatic heterocyclic group, or a hydroxy group. In addition, the hydrogen atom may be replaced by the coordinating functional group.

The substituted or unsubstituted alkylene group or the substituted or unsubstituted unsaturated hydrocarbon group that bonds to the polar bonding group is not limited in any particular manner. However, the ligands 43 preferably contain a C₁-C₄ alkylene group bonded directly to the polar bonding group. Owing to the inclusion in the ligands 43 of a C₁-C₄ alkylene group bonded directly to the polar bonding group in this manner, the ligands 43 can restrain degradation of light-emission properties caused by the deactivation of the QDs 42.

The ligands 43 may be, for example, a monomer that has the same or a different one of the coordinating functional groups at each end of the main chain and that contains at least one polar bonding group of at least one species in a part other than the ends of the main chain (i.e., in a part other than the terminal groups of the main chain). Examples of such ligands 43 include at least one species of ligands selected from the group consisting of ligands of general formula (1) below.

R¹-A¹-A²-(CH₂)ₙ—R² (1)

Note that in this general formula (1), R¹ and R² are each independently one of the coordinating functional groups. In other words, R¹ and R² may be the same coordinating functional group or different coordinating functional groups. A¹ is a substituted or unsubstituted —((CH₂)ₘ₁—X¹)ₘ₂— group. A² is a direct bond, an X² group, or a substituted or unsubstituted —((CH₂)ₘ₃—X₂)ₘ₄— group. X¹ and X² are different polar bonding groups. Numbers n and m1 to m4 are each independently an integer greater than or equal to 1. Note that n, m1, and m3 preferably are each independently an integer from 1 to 4 and that m2 and m4 preferably are each independently an integer from 1 to 10.

In addition, the substituted or unsubstituted —((CH₂)ₘ₁—X¹)ₘ₂— group is a —((CH₂)ₘ₁—X¹)ₘ₂— group that may or may not have a substituent. Similarly, the substituted or unsubstituted —((CH₂)ₘ₃—X²)ₘ₄— group is a —((CH₂)ₘ₃—X²)ₘ₄— group that may or may not have a substituent.

As described earlier, “may have a substituent” refers to both cases where a hydrogen atom (—H) is replaced by a monovalent group and cases where a methylene group (—CH₂—) is replaced by a divalent group.

Note that the alkylene group bonded to the polar bonding group may have either a straight-chain structure or a cyclic structure also when the ligands 43 have general formula (1) above. Therefore, the —((CH₂)ₘ₁—X¹)ₘ₂— group and the —((CH₂)ₘ₃—X²)ₘ₄— group may have either a straight-chain structure or a cyclic structure.

Note that the substituent, as described earlier, may be, for example, an aliphatic hydrocarbon group, an aromatic hydrocarbon group, an aromatic heterocyclic group, or a hydroxy group. In addition, the hydrogen atom may be replaced by the coordinating functional group. Therefore, the ligands of general formula (1) above may be a bifunctional molecule that has the same or a different one of the coordinating functional groups at each end of the main chain and may be a polyfunctional molecule that has one of the coordinating functional groups at each end of the main chain and on a side chain.

The use of the aforementioned ligands as the ligands 43 enables bonding the plurality of QDs 42 via the ligands 43 as shown in FIG. 1 and also enables the polar bonding groups imparting further polarity to the ligands 43. Therefore, it is possible to provide the QD-containing film 41 with high wettability to a polar solvent and high solution resistance to polar and non-polar solvents.

Note that these effects are unique to the ligands 43 that are a monomer. A polymer has a large number of repetitions of a structural unit (monomer) and generally either contains approximately at least 1,000 atoms or is polymerized to a molecular weight of 10,000 or greater. An oligomer has a small number of repetitions of a structural unit (monomer) and generally has a molecular weight of 1,000 to 10,000. Since a polymerized or oligomerized ligand consumes thiol or like coordinating functional groups that can be coordinated to the QDs 42 to extend its chain through chemical reaction, the quantity and density of the coordinating functional groups that can be coordinated to the QDs 42 decrease with the growth of the molecule. Therefore, the polymerized or oligomerized ligand is a factor that leads to large decreases in the margin and probability for the ligand to be coordinated to the QDs 42 and in the probability of achieving the insolubility effect that bonds the QDs 42 together.

In the present embodiment, the number of atoms in the straight chain of the ligand 43 is preferably approximately equal to the number of atoms in the straight chain of a known used ligand, as described above, even when polar bonding groups are contained. In addition, the ligands 43 preferably do not contain a very large number of molecules so as to easily dissolve (disperse) even in a non-polar solvent.

Therefore, the ligands of general formula (1) above, when A′ is a direct bond, is preferably such that 2≤m1×m2+n≤20 and more preferably such that 3≤m1×m2+n≤10.

If the distance between the QDs 42 that are adjacent across the ligand 43 is too short, the QDs 42 may interact with each other so that the QDs 42 can exchange electrons, which could in turn deactivate the QDs 42 and then lead to decreases in luminous efficiency and decreases in light-emission intensity.

Non-Patent Literature 1 describes that the FRET (Foerster resonance energy transfer) efficiency is less than or equal to approximately 6% when the core-to-core distance of the QDs 42 is approximately 9 nm. It is understood from this that the FRET is restrained when the core-to-core distance of the QDs 42 is approximately 9 nm. Meanwhile, the shells of typical commercial QDs have a thickness of approximately 1 to 2 nm. Therefore, the FRET efficiency can be reduced by separating the adjacent QDs 42 including their shells (i.e., the outer surfaces of the shells of the adjacent QDs 42) by a distance of at least 5 nm.

Therefore, the shortest distance between the adjacent QDs 42 is preferably at least 5 nm to prevent deactivation of the QDs 42. In contrast, if the shortest distance between the adjacent QDs 42 is too long, the QDs 42 account for a small portion of the QD-containing film 41. Therefore, when the QD-containing film 41 is used for example, as a light-emitting layer in a display element or a wavelength conversion layer in a wavelength conversion member as will be described in Embodiments 2 and 3 below, luminous efficiency could be too low. Consequently, the light-emission intensity could disadvantageously decrease. Meanwhile, if the ligands 43 are too long, undesirable non-uniform emission of light may occur when the QD-containing film 41 is used as a light-emitting layer in a display element or a wavelength conversion layer in a wavelength conversion member as described above. Therefore, when the QD-containing film 41 is used, for example, as a light-emitting layer in a display element, the adjacent QDs 42 are preferably separated by a distance of no greater than 20 nm. In addition, when the QD-containing film 41 is used, for example, as a wavelength conversion layer in a wavelength conversion member, the adjacent QDs 42 are preferably separated by a distance of no greater than 50 nm.

Note that the distance between the adjacent QDs 42 is defined as being equal to a value that remains when the number-average particle diameter of the QDs is subtracted from the average center-to-center distance of the adjacent QDs 42 (average QD center-to-center distance). The average QD center-to-center distance can be measured using, for example, a small angle x-ray scattering pattern or a cross-sectional TEM (transmission electron microscope) image of a film containing the QDs 42. Similarly, the number-average particle diameter of nanoparticles such as the QDs 42 can be measured using, for example, a cross-sectional TEM image. Note that the number-average particle diameter of nanoparticles (e.g., the QDs 42) refers to the diameter of the nanoparticles (e.g., the QDs 42) at an integrated value of 50% in a particle size distribution. To determine the number-average particle diameter of nanoparticles (e.g., the QDs 42) from a cross-sectional TEM image, the number-average particle diameter can be determined as in the following. First, from each profile obtained by, for example, TEM of the cross-sections of a prescribed number (e.g., 30) of nanoparticles (e.g., the QDs 42) that are located in proximity to each other, the area of the cross-section of each nanoparticle (e.g., each QD 42) is determined. Next, assuming that all these nanoparticles (e.g., the QDs 42) are circular, diameters are calculated that respectively give the circular areas that are equivalents of the cross-sections. An average value of the diameters is then calculated.

By setting m1×m2+n to a value greater than or equal to 2, the ligands of general formula (1) above have one of the coordinating functional groups at each end and an alkylene group bonded directly to the polar bonding group between the ends. Therefore, the degradation of light-emission properties caused by the deactivation of the QDs 42 can be restrained. Therefore, by setting m1×m2+n to a value less than or equal to 20, when the QD-containing film 41 is used, for example, as a light-emitting layer in a display element or a wavelength conversion layer in a wavelength conversion member as described above, it is possible to form the light-emitting layer or wavelength conversion layer with the QDs 42 accounting for a high proportion and with high luminous efficiency. In addition, by setting m1×m2+n to a value less than or equal to 20, the non-uniform emission of light caused by an excessive length of the ligands of general formula (1) above can be restrained.

In addition, by setting m1×m2+n to a value less than or equal to 10, the bonding strength of the QDs 42 via the ligands of general formula (1) above can be increased. Therefore, in this case, for example, the resultant QD-containing film 41 is capable of providing a stack body in which the QD-containing film 41 can be sufficiently restrained from detaching. In addition, by setting m1×m2+n to a value greater than or equal to 3, the deactivation of the QDs 42 can be more reliably restrained, and the degradation of light-emission properties caused by the deactivation of the QDs 42 can be more reliably restrained.

In addition, the ligands of general formula (1) above, when A² above is a —((CH₂)ₘ₃— X²)ₘ₄— group, is preferably such that 2≤m1×m2+m3×m4+n≤20 and more preferably such that 3≤m1×m2+m3×m4+n≤10.

As described above, if the QDs 42 are separated by too short a distance via the ligands 43, the QDs 42 can be deactivated, which could in turn lead to undesirable decreases in luminous efficiency. By setting m1×m2+m3×m4+n to a value greater than or equal to 2, the ligands of general formula (1) above have one of the coordinating functional groups at each end and an alkylene group bonded directly to the polar bonding group between the ends. Therefore, the degradation of light-emission properties caused by the deactivation of the QDs 42 can be restrained. In addition, by setting m1×m2+m3×m4+n to a value less than or equal to 20, when the QD-containing film 41 is used, for example, as a light-emitting layer in a display element or a wavelength conversion layer in a wavelength conversion member, it is possible to form the light-emitting layer or wavelength conversion layer with the QDs 42 accounting for a high proportion and with high luminous efficiency. In addition, by setting m1×m2+m3×m4+n to a value less than or equal to 20, the non-uniform emission of light caused by an excessive length of the ligands of general formula (1) above can be restrained.

In addition, by setting m1×m2+m3×m4+n to a value less than or equal to 10, the bonding strength of the QDs 42 via the ligands of general formula (1) above can be increased. Therefore, by setting m1×m2+m3×m4+n to a value less than or equal to 10, for example, the resultant QD-containing film 41 is capable of providing a stack body in which the QD-containing film 41 can be sufficiently restrained from detaching. In addition, by setting m1×m2+m3×m4+n to a value greater than or equal to 3, the deactivation of the QDs 42 can be more reliably restrained, and the degradation of light-emission properties caused by the deactivation of the QDs 42 can be more reliably restrained.

In addition, as described above, by ether such a setting that 2≤m1×m2+n≤20, preferably that 3≤m1×m2+n≤10, or such a setting that 2≤m1×m2+m3×m4+n≤20, preferably that 3≤m1×m2+m3×m4+n≤10, the contact angle between the QD-containing film 41 and a ZnO-dispersed solution in which, for example, ZnO is dispersed in ethanol or a like alcoholic solvent can be rendered, for example, less than or equal to 105°. Hence, the ZnO-dispersed solution can be well applied to the QD-containing film 41, enabling stacking a ZnO layer on the QD-containing film 41 with no gap being left at the interface with the QD-containing film 41.

The ligands 43 are not limited in any particular manner so long as the ligands 43 include at least two coordinating functional groups of at least one species and include at least one polar bonding group of at least one species at a site other than the site at which the ligands 43 are coordinated to the QDs 42.

Examples of the ligands including an ether bonding group as a polar bonding group include 1-amino-3,6,9,12,15,18-hexaoxahenicosan-21-oic acid, 2-[2-(2-aminoethoxy)ethoxy]acetic acid, 2,2′-(ethylenedioxy)diethanethiol, and 2,2′-oxydiethanethiol.

Examples of the ligands including a sulfide bonding group as a polar bonding group include bis(2-mercaptoethyl)sulfide.

Examples of the ligands including an imine bonding group as a polar bonding group include glyoxal bis(2-hydroxyanil), 4-aminobenzamidine dihydrochloride, 6-amidino-2-naphthol methanesulfonate, aminoacetamidine dihydrobromide, and 3-amino-5-mercapto-1,2,4-triazole.

Examples of the ligands including an ester bonding group as a polar bonding group include ethylene glycol bis(3-mercaptopropionate).

Examples of the ligands including an amide bonding group as a polar bonding group include bis(hexamethylene)triamine.

Examples of the ligands including a carbonyl group as a polar bonding group include 2′,5′-dihydroxy acetophenone.

Any one of these ligands may be used alone. Alternatively, two or more of the ligands may be used in the form of mixture where appropriate.

Particularly preferred among these exemplary ligands used as the ligands 43 is 2,2′-(ethylenedioxy)diethanethiol.

By using 2,2′-(ethylenedioxy)diethanethiol as the ligands 43, when the QD-containing film 41 is used, for example, as a light-emitting layer in a display element or a wavelength conversion layer in a wavelength conversion member, it is possible to form the light-emitting layer or wavelength conversion layer with the QDs 42 accounting for a high proportion and with high luminous efficiency. In addition, by using 2,2′-(ethylenedioxy)diethanethiol as the ligands 43, the degradation of light-emission properties caused by the deactivation of the QDs 42 can be restrained, and the non-uniform emission of light caused by an excessive length of the ligands 43 can be restrained. In addition, the bonding strength of the QDs 42 via the ligands 43 can be increased, and the resultant QD-containing film 41 is capable of providing a stack body in which the film (layer) obtained using the QD-containing film 41 can be sufficiently restrained from detaching.

The QD-containing film 41 needs only to contain the QDs 42 and the ligands 43. To obtain the QD-containing film 41 capable of delivering high solution resistance to polar and non-polar solvents and also improving wettability to a polar solvent, the QD-containing film 41 preferably contains only the QDs 42 and the ligands 43.

The composition ratio of the QDs 42 and the ligands 43 in the QD-containing film 41 ([QDs 42]:[ligands 43]) is not limited in any particular manner and is preferably in a range of 2:0.25 to 2:6 in weight and more preferably in a range of 2:1 to 2:4. It is hence possible to form the QD-containing film 41 that enables the plurality of QDs 42 to bond to each other through the ligands 43, that delivers high solution resistance to polar and non-polar solvents, and that improves wettability to a polar solvent. In addition, ligands are generally often insulating because ligands have a molecular structure made largely of organic materials. Therefore, although depending on usage, for example, when the QD-containing film 41 is used as a light-emitting layer in a QLED, the QD-containing film 41 preferably does not contain an excessive amount of ligands in view of carrier injection in the light-emission properties thereof. Therefore, the composition ratio is preferably in the aforementioned ranges.

Note that as described earlier, the QD-containing film 41 preferably contains only the QDs 42 and the ligands 43. However, depending on usage and other factors, where necessary, the QD-containing film 41 may contain, for example, components other than the QDs 42 and the ligands 43 such as a resin and various additives so long as those components do not disrupt the ligand exchange and the aforementioned effects of the present application. In addition, although the QD-containing film 41 preferably does not contain ligands other than the ligands 43, the QD-containing film 41 may contain ligands other than the ligands 43 so long as those ligands do not disrupt the aforementioned effects of the present application. In addition, although the QD-containing film 41 preferably does not contain a solvent, the QD-containing film 41 may contain a solvent, for example, as a trace component (impurity).

Note that when the QD-containing film 41 contains, for example, a resin as a component other than the QDs 42 and the ligands 43, the resin preferably has high solution resistance to polar and non-polar solvents and also high wettability to a polar solvent.

In addition, the ligands other than the ligands 43 that may be contained in the QD-containing film 41 may be, for example, monofunctional non-polar ligands having one of the coordinating functional groups illustratively described earlier and used in the manufacture of the QD-containing film 41. These monofunctional non-polar ligands are non-polar ligands having a single coordinating functional group. The monofunctional non-polar ligands are not limited in any particular manner and may be, for example, either a monomer or an oligomer. An example of the monofunctional non-polar ligands is oleic acid.

The thickness of the QD-containing film 41 can be specified as appropriate depending on usage and is not limited in any particular manner. It should be noted however that the thickness of the QD-containing film 41 has a lower limit that is equal to the outermost particle diameter of the single QD 42. When the QD-containing film 41 is used, for example, as a light-emitting layer in a display element, the QD-containing film 41 is preferably filled thickness-wise with at least one QD 42 with no gap. As described earlier, even when the shell is taken into account, the outermost particle diameter of the QD 42 is, for example, approximately from 1 to 15 nm and preferably approximately from 3 to 15 nm, and the overlapping layer number of the QDs 42 in the light-emitting layer or the wavelength conversion layer is, for example, from 1 to 10 layers. Therefore, when the QD-containing film 41 is used as the light-emitting layer, the thickness (layer thickness) of the QD-containing film 41 (i.e., the light-emitting layer) may be equal to anyknown, publicly known thickness (layer thickness) and is, for example, approximately from 1 to 150 nm and preferably from 3 to 150 nm.

In addition, when the QD-containing film 41 is used, for example, as a wavelength conversion layer in a wavelength conversion member, the thickness (layer thickness) of the QD-containing film 41 (i.e., the wavelength conversion section layer) is preferably from 0.1 to 100 μm and more preferably from 0.1 to 3 μm. For example, when a wavelength conversion layer that contains a functional material such as a binder (binder resin) other than the QDs 42 and the ligands 43 is formed as the QD-containing film 41, the thickness (layer thickness) of the QD-containing film 41 (i.e., the wavelength conversion section layer) may be equal to any known, publicly known thickness (layer thickness) and may in such a case be, for example, approximately 100 μm. Meanwhile, a wavelength conversion layer as the QD-containing film 41 is made only of the QDs 42 and the ligands 43, the thickness of the QD-containing film 41 is preferably from 0.1 to 3 μm.

### Method of Forming QD-Containing Film 41

FIG. 2 is a flow chart representing an exemplary method of forming the QD-containing film 41 in accordance with the present embodiment.

To form the QD-containing film 41, as shown in FIG. 2, first, a film containing the QDs 42 and monofunctional non-polar ligands having a single coordinating functional group capable of being coordinated to the QDs 42 (hereinafter, will be referred to as a “precursor film”) is formed on a support body (step S11; a precursor film forming step). Next, a ligand solution containing the ligands 43 is supplied onto the precursor film to exchange (replace) the monofunctional non-polar ligands coordinated to the QDs 42 in the precursor film with the ligands 43 (step S12; ligand exchange step). Thereafter, heating (step S13; heating step), washing (step S14; washing step), and drying (step S15; drying step) are performed as necessary.

In step S11 above, the precursor film can be obtained by applying a QD colloidal solution containing the QDs 42, monofunctional non-polar ligands having a single coordinating functional group and being capable of being coordinated to the QDs 42, and a solvent onto the support body and then drying out the QD colloidal solution.

The monofunctional non-polar ligands may be, for example, those ligands given as examples of the monofunctional non-polar ligands used in the manufacture of the QD-containing film 41. In addition, the coordinating functional groups in the monofunctional non-polar ligands may be those coordinating functional groups given above as examples as described earlier.

Note that the QD colloidal solution may be a commercially available QD colloidal solution, and the monofunctional non-polar ligands may be, for example, ligands contained in a commercially available QD colloidal solution. Commercially available QD colloidal solutions generally contain monofunctional non-polar ligands. This is because the QDs can be restrained from aggregating by coordinating ligands to the surface of the QDs.

In the QD colloidal solution, the concentration of the QDs 42, the concentration of the monofunctional non-polar ligands, and the concentration of the monofunctional non-polar ligands in the QDs 42 may be specified similarly to a known manner and are not limited in any particular manner so long as the QDs 42, the monofunctional non-polar ligands, and the monofunctional non-polar ligands in the QDs 42 have such a concentration or viscosity that allows for application of these materials. For example, when spin-coating is used, the QD concentration is typically specified to approximately 5 to 20 mg/mL to achieve a practical QD film thickness. It should be understood however that this example is for illustrative purposes only and that the optimal concentration may vary depending on the film forming method.

The QD colloidal solution may be dried by, for example, baking or like thermal drying. The drying temperature (e.g., baking temperature) may be specified as appropriate in accordance with the type of the solvent in such a manner as to remove the unnecessary solvent contained in the QD colloidal solution. Therefore, the drying temperature is not limited in any particular manner and is preferably, for example, from 60 to 120° C. Hence, the unnecessary solvent contained in the QD colloidal solution can be removed without thermally damaging the QDs 42. Note that the drying time may be specified as appropriate in accordance with the drying temperature in such a manner as to remove the unnecessary solvent contained in the QD colloidal solution and is not limited in any particular manner.

In step S12, the ligand solution is supplied to the precursor film by, for example, a method of disseminating the ligand solution over the precursor film. Note that the ligand solution may be, for example, either spread like mist by spraying or spread like droplets by dropwise dispensation. The ligand solution may be spread (supplied) by, for example, inkjet technology or using a mist spray device. In addition, to apply the ligand solution uniformly across the precursor film, the ligand solution may be supplied (e.g., spread) onto the precursor film, and thereafter the supplied ligand solution be applied to the surface of the precursor film by spin-coating.

As the ligand solution is brought into contact with the precursor film, the monofunctional non-polar ligands coordinated to the QDs 42 in the precursor film are replaced by the ligands 43. Therefore, the monofunctional non-polar ligands coordinated to the QDs 42 in the precursor film can be replaced by the ligands 43 by permeating the precursor film with the ligand solution. Note that throughout the following description, the replacing by the ligands 43 of the monofunctional non-polar ligands coordinated to the QDs 42 in the precursor film in this manner will be referred to simply as “ligand exchange.”

As described earlier, the ligand 43 has at least two coordinating functional groups of at least one species for coordination to the QDs 42. Therefore, the ligand exchange described above causes the ligands 43 to couple the plurality of QDs 42 together in the precursor film. Consequently, the QDs 42 in the precursor film are cured and become insoluble in a rinse liquid.

Note that to perform the ligand exchange described above, a ligand solution containing the ligands 43 and the solvent needs only to be supplied to, and brought into contact with, the precursor film. No heating is needed. When the QD-containing film 41 is, for example, a light-emitting layer in a light-emitting element or a wavelength conversion layer in a wavelength conversion member, the ligand solution permeates the precursor film immediately after the ligand solution is supplied to the precursor film, when the typical layer thickness of the light-emitting layer or the wavelength conversion layer is taken into account. Therefore, there is no particular need for management and control of the time taken by the ligand exchange.

Note that where necessary, a retention time may be specified for permeation by the ligand solution, and heating (thermal drying; step S13) may be performed as described above to remove the unnecessary solvent contained in the QD-containing film 41 immediately after the ligand exchange to complete the ligand exchange.

Note that the heating temperature and the heating time in step S13 above may be specified as appropriate in such a manner as to remove the unnecessary solvent as described above and are not limited in any particular manner.

Note that step S13 to step S15 may be skipped. But, the QD-containing film 41 obtained by removing, after the ligand exchange, the unnecessary solvent used in the ligand exchange contains, as the unnecessary ligands, the monofunctional non-polar ligands replaced by the ligands 43 and no longer coordinated to the QDs 42 and the excess ligands 43 not coordinated to the QDs 42.

Accordingly, by washing (rinsing) in a rinse liquid in step S14, the unnecessary ligands contained in the QD-containing film 41 obtained by removing, after the ligand exchange, the unnecessary solvent used in the ligand exchange (i.e., the QD-containing film 41 immediately after being formed) can be removed.

Thereafter, in step S15, by performing drying (thermal drying) to remove the rinse liquid used in the washing, the QD-containing film 41 can be obtained that contains the QDs 42 and the ligands 43 coordinated to the QDs 42 and from which the unnecessary ligands have been removed (i.e., that practically does not contain unnecessary ligands).

Note that this washing method is not limited in any particular manner and may be any one of publicly known various methods. For example, a sufficient amount of a rinse liquid needs only to be supplied to the QD-containing film 41 immediately after the QD-containing film 41 is formed, and a sufficient amount of a rinse liquid may be supplied and applied as described in an example detailed later.

The solubility of ligands as such slightly differs from the solubility of the ligands coordinated to the QDs 42 and the solubility of the QDs 42. Therefore, the solvent in the QD colloidal solution is not limited in any particular manner so long as the solvent can dissolve the QDs 42 as such, the monofunctional non-polar ligands as such, the QDs 42 to which the monofunctional non-polar ligands are coordinated, and the monofunctional non-polar ligands coordinated to the QDs 42. Meanwhile, if a solvent that dissolves the QDs 42 in the precursor film is used as the solvent in the ligand solution, this solvent not only replaces ligands, but also dissolves the precursor film. Therefore, the solvent in the ligand solution is not limited in any particular manner so long as the solvent does not dissolve the QDs 42 as such, the monofunctional non-polar ligands as such, the QDs 42 to which the monofunctional non-polar ligands are coordinated, and the monofunctional non-polar ligands coordinated to the QDs 42 and can dissolve the ligands 43. In addition, if the ligands 43 are coordinated to the QDs 42 by ligand exchange, the QDs 42 to which the ligands 43 are coordinated become insoluble and no longer dissolve in any solvent. Therefore, the solvent used as the rinse liquid is not limited in any particular manner so long as the solvent dissolves the monofunctional non-polar ligands coordinated to the QDs 42 and also dissolves the excess ligands 43 not coordinated to the QDs 42 and the monofunctional non-polar ligands.

Note that QDs generally easily deteriorate in water. In addition, the QDs 42 as such, the monofunctional non-polar ligands as such, the QDs 42 to which the monofunctional non-polar ligands are coordinated, and the monofunctional non-polar ligands coordinated to the QDs 42 dissolve in a non-polar solvent. In contrast, the ligands 43 as such dissolve in a polar solvent. Therefore, the solvent in the QD colloidal solution and the rinse liquid are non-polar solvents. In addition, the solvent in the ligand solution is a polar solvent.

The non-polar solvent has, for example, a Hildebrand solubility parameter (6 value) preferably of 9.3 or lower and more preferably from 7.3 to 9.3, both inclusive. In addition, the non-polar solvent has, for example, a dielectric constant (Cr value) preferably of 6.02 or lower and more preferably from 1.89 to 6.02, both inclusive, when measured at around 20° C. to 25° C. These non-polar solvents make so good solvents of the QDs 42 to which the monofunctional non-polar ligands are coordinated as to dissolve at least 50% of the QDs 42 to which the monofunctional non-polar ligands are coordinated. In addition, the non-polar solvent does not degrade the QDs 42 and does not dissolve the QDs 42 to which the ligands 43 are coordinated. Therefore, the non-polar solvent is more preferably the aforementioned solvent.

The non-polar solvent is not limited in any particular manner and may be, for example, at least one species of solvent selected from the group consisting of toluene, hexane, octane, and chlorobenzene. Toluene, hexane, and octane are non-polar solvents with a δ value of from 7.3 to 9.3, both inclusive, and an Er value of from 1.89 to 6.02, both inclusive, particularly well dissolve, for example, the QDs 42 to which the monofunctional non-polar ligands are coordinated, and are easily available. Chlorobenzene is a non-polar solvent with an Er value of 6.02 or lower, particularly well dissolve, for example, the QDs 42 to which the monofunctional non-polar ligands are coordinated, and is easily available. Therefore, the non-polar solvent is particularly preferably the aforementioned solvent.

Meanwhile, the polar solvent is, for example, preferably a solvent with a δ value higher than 9.3 and more preferably a solvent with a δ value from 9.3 exclusive to 12.3 inclusive. In addition, the polar solvent more preferably has a δ value of 10 or higher. Therefore, the polar solvent is even more preferably a solvent with a δ value of from 10 to 12.3, both inclusive. In addition, the polar solvent is, for example, preferably a solvent with an Er value higher than 6.02 and more preferably a solvent with an Er value of from 6.02 exclusive to 46.7 inclusive.

The polar solvent is not limited in any particular manner and may be, for example, at least one species of solvent selected from the group consisting of propylene glycol monomethyl ether acetate (PGMEA), methanol, ethanol, acetonitrile, and ethylene glycol. This at least one species of solvent selected from the group consisting of PGMEA, methanol, ethanol, acetonitrile, and ethylene glycol is a polar solvent with a solvent degree parameter of 10 or higher, is easily available, and dose not contain a very large number of molecules. Therefore, the ligands 43 can be uniformly dissolved.

Note that in the QD colloidal solution, the concentration of the QDs 42, the concentration of the monofunctional non-polar ligands, and the concentration of the monofunctional non-polar ligands in the QDs 42 may be specified similarly to a known manner and are not limited in any particular manner so long as the QDs 42, the monofunctional non-polar ligands, and the monofunctional non-polar ligands in the QDs 42 have such a concentration or viscosity that allows for application of these materials. For example, when spin-coating is used, the QD concentration is typically specified to approximately 5 to 20 mg/mL to achieve a practical QD film thickness. It should be understood however that this example is for illustrative purposes only and that the optimal concentration may vary depending on the film forming method.

In addition, the concentration of the ligands 43 in the ligand solution is not limited in any particular manner and preferably from 0.01 mol/L to 2.0 mol/L.

To perform ligand exchange, the ligand solution needs to dissolve (disperse) the monofunctional non-polar ligands that were coordinated to the QDs 42 before the ligand exchange. Therefore, the concentration of the ligands 43 is preferably within the foregoing range to strike a good balance between the supply of the ligands 43 and the dissolution of the ligands 43 in the ligand solution.

In addition, as described earlier, the composition ratio of the QDs 42 and the ligands 43 in the QD-containing film 41 ([QDs 42]: [ligands 43]) is preferably in a range of 2:0.25 to 2:6 in weight and more preferably in a range of 2:1 to 2:4. The supply amount of the ligands 43 varies with, for example, the composition and thickness of the precursor film, the method of adding the ligands 43, and the size of the light-emitting region. However, the supply amount of the ligands 43 per QD 42 is sufficient regardless of these conditions, and for this reason, the amount of the ligands 43 actually coordinated to the QDs 42 tends to depend on the concentration of the ligands 43 in the ligand solution. Then, in step S13, the excess ligands 43 that are coordinated to the QDs 42 are removed by a rinse liquid. In addition, in step S12, an amount of ligands 43 that is excessive in view of the composition ratio of the QDs 42 and the ligands 43 in the QD-containing film 41 described above are supplied to the QDs 42 so that the composition ratio of the QDs 42 and the ligands 43 in the QD-containing film 41 can eventually fall in the range by removing the excess ligands 43 in step S14. Therefore, if the concentration of the ligands 43 in the ligand solution is in the range described above, the composition ratio of the QDs 42 and the ligands 43 that falls in the desirable range described above can be obtained in the eventually obtainable QD-containing film 41 by supplying the ligand solution in such a manner that the ligand solution can permeate the entire precursor film on which ligand exchange is performed. Hence, the QD-containing film 41 can be formed in which the plurality of QDs 42 are bonded together via the ligands 43, that has high solution resistance to polar and non-polar solvents, that can improve wettability to a polar solvent, and that restrains decreases in carrier injection efficiency.

In addition, the viscosity of the ligand solution may be adjusted to a desirable range, if necessary, by adjusting, for example, the temperature and pressure at which the ligand solution is applied. Therefore, the viscosity of the ligand solution is not limited in any particular manner and is preferably from 0.5 to 500 mPa·s and more preferably from 1 to 100 mPa·s. Hence, the non-uniform contact between the precursor film and the ligand solution and the non-uniform permeation of the precursor film by the ligand solution can be reduced, and the non-uniform coating of the ligand solution in the drying step can be reduced. Consequently, the thickness of the QD-containing film 41 eventually obtained can be easily adjusted.

Note that viscosity can be measured using, for example, a known, publicly known rotational viscometer or B-type viscometer. The present embodiment presents measurements obtained using a vibrating viscometer VM-10A-L manufactured by CBC Materials Co., Ltd. in accordance with “JIS 8803Z: 2011 Methods for viscosity measurement of liquid.”

In addition, the ligand solution spread over the precursor film preferably has a liquid drop diameter of from 10 μm to 1 mm, both inclusive. Hence, when the ligand solution is spread by, for example, mechanical spraying (mist spray device) or inkjet printing, pixels can be formed with high definition so long as the liquid drop diameter is compatible with the particular method.

Note that the ligands 43 being coordinated to the QDs 42 can be verified through the fact that the QDs 42 to which the ligands 43 are coordinated do not dissolve in a rinse liquid.

In addition, depending on the ligands coordinated, whether or not the ligands are coordinated to the QDs 42 can be verified, for example, by measurement by Fourier transform infrared spectroscopy (FT-IR) (hereinafter, referred to as “FT-IR measurement”). For example, when either the ligands coordinated to the QDs 42 have a —C(═O)OH group as a coordinating functional group coordinated to the QDs 42 or the coordinating functional group coordinated to the QDs 42 has a —P(═O) group, the vibration found in FT-IR measurements slightly differs between a condition where the ligands are not coordinated to the QDs 42 and a condition where the ligands are coordinated to the QDs 42, which causes a detection peak shift. Therefore, hence, it can be checked whether either the monofunctional non-polar ligands or the ligands 43 are coordinated to the QDs 42.

In addition, the ligands 43 being coordinated to the QDs 42 can also be verified through the fact that the peak for the monofunctional non-polar ligands that existed prior to the ligand exchange is no loner found after the ligand exchange, which indicates that the ligands 43 have all been substituted in the ligand exchange.

Furthermore, when either one or both of the monofunctional non-polar ligands and the ligands 43 include a functional group that produces a unique peak other than the coordinating functional groups coordinated to the QDs 42, coordination can be verified through the detected amount thereof. Such a functional group is, for example, an ether group, an ester group, and a C═C bond in oleic acid. The ligand exchange having been performed can be verified particularly when a unique peak that existed prior to the ligand exchange is no longer detected after the ligand exchange or when a new unique peak is detected after the ligand exchange.

Next, the effects described above will be described in more detail by means of examples of the disclosure and comparative examples.

First, results are presented of verifying wettability of the QD-containing film 41 to a polar solvent.

### Example 1

First, green QDs that included a CdSe core with a particle diameter of 3 nm and a ZnS shell with a thickness (shell thickness) of 1 nm were synthesized as the QDs 42 by a publicly known method. Next, a colloidal solution was prepared that contained: the green QDs (20 mg/mL); 1-octanethiol (CH₃ (CH₂)₇SH), which was monofunctional non-polar ligands having a single coordinating functional group capable of being coordinated to the green QDs (ligand concentration: 20 wt %); and toluene. Next, the colloidal solution was applied by spin-coating at 3,000 rpm onto a glass substrate as a support body for measuring optical properties and subsequently baked at 100° C. to remove unnecessary solvent, and was dried. Hence, a precursor film containing the green QDs and octanethiol was formed on the glass substrate. The precursor film had a thickness of 30 nm. Note that the thickness of the precursor film was measured using a stylus profilometer manufactured by KLA-Tencor Corporation.

Next, a 0.1 mol/L acetonitrile solution containing 2,2′-(ethylenedioxy)diethanethiol (HSCH₂CH₂OCH₂CH₂OCH₂CH₂SH) was prepared as a ligand solution containing the ligands 43.

Next, the ligand solution (200 μL) was spread over the precursor film, and 10 seconds later, the spread ligand solution was applied by spin-coating at 3,000 rpm to exchange ligands.

Next, the acetonitrile contained in the film following the ligand exchange was removed by baking at 100° C. for 10 minutes. Hence, the QD-containing film 41 was formed containing the green QDs and 2,2′-(ethylenedioxy)diethanethiol.

Next, the wettability of the QD-containing film 41 following the acetonitrile removal (hereinafter, will be referred to as the “immediately post-film formation, QD-containing film 41”) was evaluated. The wettability was evaluated by measuring the contact angle between the QD-containing film 41 and water at 25° C. using a microscope-based contact angle meter (product name: CA-QI series, manufactured by Kyowa Interface Science Co., Ltd.) in accordance with the sessile drop method described in JIS R3257:1999.

Next, 100 μL of toluene as a rinse liquid was spread onto the immediately post-film formation, QD-containing film 41, and 10 seconds later, the spread toluene was applied by spin-coating at 3,000 rpm, washed (toluene washing, rinsing), and thereafter heated at 100° C.

Next, the wettability of the QD-containing film 41 after this toluene washing (specifically, the QD-containing film 41 as obtained by heating and drying after being washed in toluene) was evaluated by the above-described method.

### COMPARATIVE EXAMPLE 1

A precursor film as an immediately post-film formation, comparative QD-containing film 141 was prepared similarly to Example 1, and the wettability of the immediately post-film formation, comparative QD-containing film 141 was evaluated by the same method as in Example 1.

Next, 100 μL of toluene as a rinse liquid was spread onto this immediately post-film formation, comparative QD-containing film 141, and 10 seconds later, the spread toluene was applied by spin-coating at 3,000 rpm to wash the immediately post-film formation, comparative QD-containing film 141 in toluene.

As a result of this, the comparative QD-containing film 141 dissolved in the toluene. Therefore, the wettability of this immediately post-film formation, comparative QD-containing film 141 was not able to be measured.

### COMPARATIVE EXAMPLE 2

The same procedures and measurements were carried out as in Example 1, except that 1,2-ethanedithiol (HSCH₂CH₂SH) was used in place of 2,2′-(ethylenedioxy)diethanethiol of Example 1 as ligands for ligand exchange.

In other words, in the present comparative example, a comparative QD-containing film 142 containing 1,2-ethanedithiol in place of 2,2′-(ethylenedioxy)diethanethiol was formed. Then, the wettability of the comparative QD-containing film 142 which had been just formed (i.e., after the acetonitrile removal) was evaluated by the same method as in the example of the disclosure. In addition, 100 μL of toluene as a rinse liquid was spread onto this immediately post-film formation, comparative QD-containing film 142, and 10 seconds later, the spread toluene was applied by spin-coating at 3,000 rpm, washed in toluene, and thereafter heated at 100° C. Then, the wettability of this immediately post-film formation, comparative QD-containing film 142 (specifically, the comparative QD-containing film 142 as obtained by heating and drying after being washed in toluene) was evaluated by the same method as in Example 1.

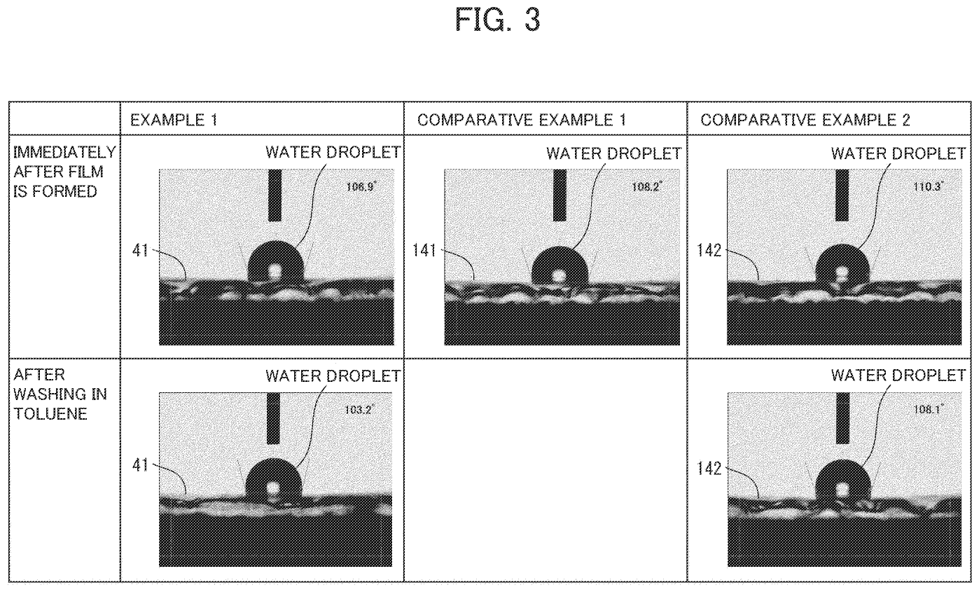

FIG. 3 and Table 1 show the wettability of the immediately post-film formation, QD-containing film 41 and the wettability of the QD-containing film 41 as was after being washed in toluene, both formed in Example 1, the wettability of the immediately post-film formation, comparative QD-containing film 141 formed in Comparative Example 1, and the wettability of the immediately post-film formation, comparative QD-containing film 142 and the wettability of the comparative QD-containing film 142 as was after being washed in toluene, both formed in Comparative Example 2.

TABLE 1

| | | Comparative | Comparative |
|---|---|---|---|
| | Example 1 | Example 1 | Example 2 |
| QD | CsS/ZnS | CsS/ZnS | CsS/ZnS |
| Ligands | *1 | *2 | *3 |
| Contact Angle | 106.9° | 108.2° | 110.3° |
| between QD- | | | |
| containing Film | | | |
| immediately after | | | |
| Being Formed and | | | |
| Water | | | |
| Contact Angle | 103.2° | Immeasurable | 108.1° |
| between QD- | | | |
| containing Film after | | | |
| Being Washed in | | | |
| Toluene and Water | | | |

*1: 2,2′-(ethylenedioxy)diethanethiol
*2: 1-octanethiol
*3: 1,2-ethanedithiol

It is understood that, as described earlier, the QD-containing film 41 formed in Example 1 does not dissolve in toluene, which is a non-polar solvent, and has solution resistance to a non-polar solvent as demonstrated in Comparative Example 1. In addition, it is understood from FIG. 3 and Table 1 that the QD-containing film 41 formed in Example 1 has a smaller contact angle with water (water solvent, water droplet), which is a highly polar solvent, and has higher hydrophilic (wettability), than the comparative QD-containing film 142. It is understood from this that even with non-polar monofunctional ligands and non-polar bifunctional ligands both of which have no polarity-imparting bonds, wettability to a polar solvent can be improved, by replacing non-polar bifunctional ligands having no polarity-imparting bonds with bifunctional ligands having a polarity-imparting bond (e.g., ether bond) in the main chain (straight chain), which is a type of the ligands 43 in accordance with the present embodiment.

Next, results are presented of verifying the solution resistance of the QD-containing film 41 to non-polar solvents.

### Example 2

First, red QDs that included a CdSe core with a particle diameter of 6 nm and a ZnSe shell with a thickness (shell thickness) of 1 nm and that had a peak emission wavelength of 630 nm were synthesized as the QDs 42 by a publicly known method. Next, a colloidal solution was prepared that contained: the red QDs (20 mg/mL); 1-octanethiol (CH₃ (CH₂)₇SH), which was monofunctional non-polar ligands having a single coordinating functional group capable of being coordinated to the green QDs (ligand concentration: 20 wt %); and toluene. Next, the colloidal solution was applied by spin-coating at 2,000 rpm onto a glass substrate as a support body for measuring optical properties and subsequently baked at 100° C. to remove unnecessary solvent, and was dried. Hence, a precursor film containing the red QDs and octanethiol was formed on the glass substrate. The precursor film had a thickness of 60 to 65 nm as measured using the same stylus profilometer as in Example 1.

Next, a 0.1 mol/L acetonitrile solution containing 2,2′-(ethylenedioxy)diethanethiol was prepared as a ligand solution containing the ligands 43 in the same manner as in Embodiment 1.

Next, the ligand solution (200 μL) was spread over the precursor film, and 10 seconds later, the spread ligand solution was applied by spin-coating at 2,000 rpm to exchange ligands.

Next, the acetonitrile in the film immediately following the ligand exchange was removed by baking at 100° C. for 10 minutes. Hence, the QD-containing film 41 was formed containing the red QDs and 2,2′-(ethylenedioxy)diethanethiol.

Next, the thickness of the immediately post-film formation, QD-containing film 41 (i.e., after the acetonitrile removal) was measured using the same stylus profilometer as in Example 1.

Thereafter, a sufficient amount of toluene as a rinse liquid was spread over the immediately post-film formation, QD-containing film 41, and 10 seconds later, the spread toluene was applied by spin-coating at 2,000 rpm, washed in toluene, and thereafter heated at 100° C. Note that the “sufficient amount” here refers to a sufficient amount for the size of the substrate used in the support body. Note that in the present embodiment, a 25 mm×25 mm×0.7 mm glass substrate was used as the glass substrate as the support body as an example in the examples of the disclosure and the comparative examples. Therefore, 200 μL of a rinse liquid was used as a sufficient amount of a rinse liquid.

Thereafter, the thickness of the QD-containing film 41 after the toluene washing (specifically, the QD-containing film as obtained by heating and drying after being washed in toluene), and the optical absorbency and light-emission intensity of the QD-containing film 41 after the toluene washing to light with a wavelength of 450 nm was measured.

Note that the thickness of the QD-containing film 41 after the toluene washing was measured using the same stylus profilometer as in Example 1. In addition, the optical absorbency of the QD-containing film 41 after the toluene washing to light with a wavelength of 450 nm was measured using a UV-Vis (ultraviolet-visible) spectrophotometer. The light-emission intensity of the QD-containing film 41 after the toluene washing to light with a wavelength of 450 nm was measured using a PL (photoluminescence) lifetime meter.

In addition, the QD-containing film 41 after the toluene washing was further washed in a sufficient amount of toluene by a method similar to the method described above and dried. Then, the thickness, optical absorbency, and light-emission intensity of the QD-containing film 41 after this re-washing in toluene to light with a wavelength of 450 nm were further measured by a method similar to the method described above.

### COMPARATIVE EXAMPLE 3

The same procedures and measurements were carried out as in Example 2, except that no ligand exchange was performed. Specifically, the colloidal solution prepared in Example 2 was applied onto a glass substrate as a support body by spin-coating at 2,000 rpm and thereafter baked at 100° C. to remove an unnecessary solvent, and was dried out. Hence, a precursor film containing the red QDs and octanethiol was formed as a comparative QD-containing film on the glass substrate. The thickness of the comparative QD-containing film (precursor film) as measured using the same stylus profilometer as Example 1 was from 60 to 65 nm. Next, a sufficient amount of toluene as a rinse liquid was spread over the comparative QD-containing film similarly to Example 2, and 10 seconds later, the spread toluene was applied by spin-coating at 2,000 rpm, washed in toluene, and thereafter heated at 100° C.

Thereafter, the thickness, optical absorbency, and light-emission intensity of the comparative QD-containing film after the toluene washing (specifically, the comparative QD-containing film as obtained by heating and drying after the toluene washing) to light with a wavelength of 450 nm were measured by a method similarly to Example 2.

Next, the comparative QD-containing film after the toluene washing was further washed in a sufficient amount of toluene by a method similar to the method described above and dried. Then, the thickness, optical absorbency, and light-emission intensity of the comparative QD-containing film after this re-washing in toluene to light with a wavelength of 450 nm were further measured by a method similar to the method described above.

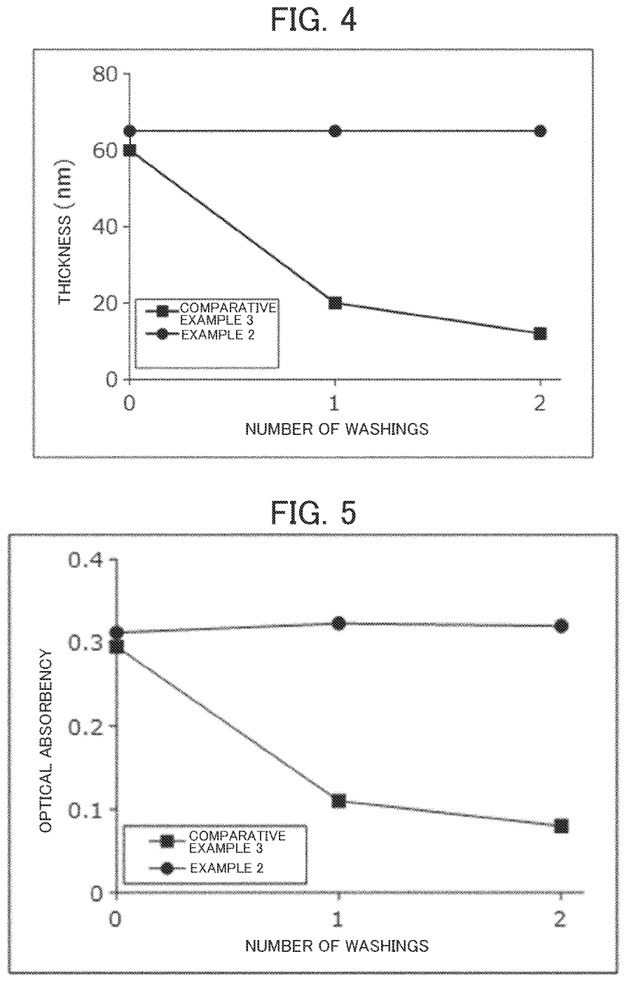

FIG. 4 is a graph representing a relationship between the thickness and the number of washings of the QD-containing films in accordance with Example 2 and Comparative Example 3 after being washed in toluene.

As can be understood from Comparative Example 3 shown in FIG. 4, the comparative QD-containing film using non-polar monofunctional ligands having no polarity-imparting bonds has such low solution resistance to toluene (rinse liquid), which is a non-polar solvent, that the thickness thereof decreases in every washing. In contrast, as understood from Example 2 shown in FIG. 4, the QD-containing film 41 using the ligands 43 in accordance with the present embodiment as ligands has such high solution resistance to toluene (rinse liquid), which is a non-polar solvent, that the thickness thereof does not change in washing. In addition, it is understood that the QD-containing film 41 can be retained after being washed in the rinse liquid, by rendering the QD-containing film 41 subjected to the ligand exchange insoluble to the rinse liquid. Therefore, it is understood that the present embodiment can provide a QD-containing film with high solution resistance to a non-polar solvent.

In addition, FIG. 5 is a graph representing a relationship between the optical absorbency to light with a wavelength of 450 nm and the number of washings of the QD-containing films in accordance with Example 2 and Comparative Example 3 after being washed in toluene.

As can be understood from the results shown in FIG. 5, the comparative QD-containing film in accordance with Comparative Example 3 has such low solution resistance to the rinse liquid that the optical absorbency thereof decreases in washing. In contrast, the QD-containing film 41 in accordance with Example 2 shows no decreases in the optical absorbency in washing. It is understood from this that the present embodiment can restrain the degradation of the QD-containing film 41 in washing and enables the manufacture of a light-emitting element or a wavelength conversion member with excellent light-emission properties by using the QD-containing film 41 as a light-emitting layer or a wavelength conversion layer in the light-emitting element.

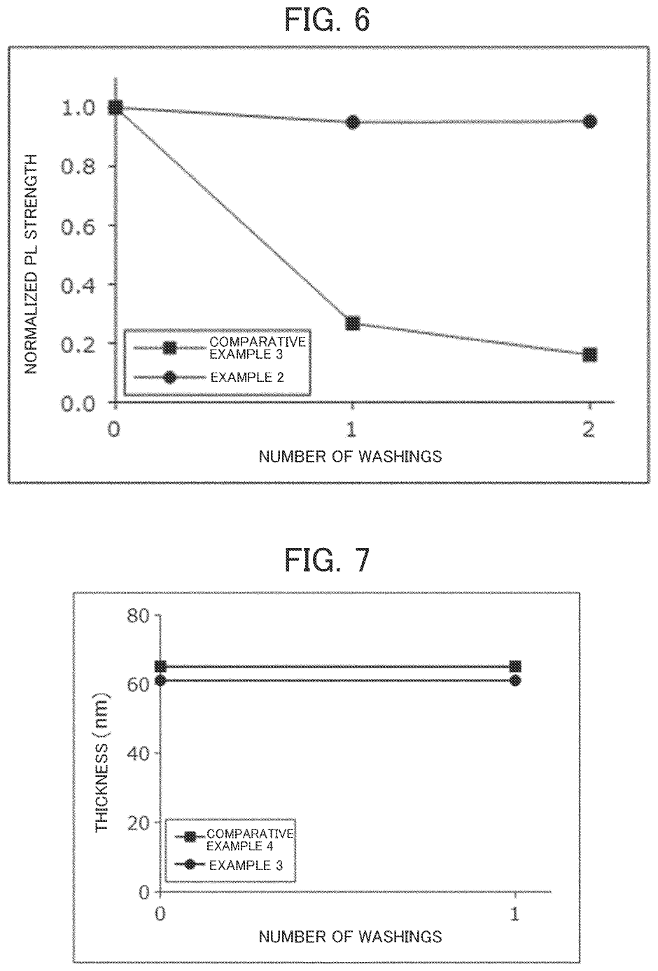

FIG. 6 is a graph representing a relationship between the light-emission intensity to light with a wavelength of 450 nm and the number of washings of the QD-containing films in accordance with Example 2 and Comparative Example 3 after being washed in toluene. Note that in FIG. 6, as a light-emission intensity, each shows a normalized PL intensity with the PL (photoluminescence) intensity of the QD-containing films before washing being 100% (PL intensity=1.0).

Referring to FIG. 6, the comparative QD-containing film in accordance with Comparative Example 3 has such low solution resistance to the rinse liquid that the light-emission intensity thereof decreases in washing. In contrast, the QD-containing film 41 in accordance with Example 2 shows almost no decreases in the light-emission intensity in washing, and the value before the washing is more or less retained. It is understood from this that the present embodiment can restrain the degradation of the QD-containing film 41 in washing and enables the manufacture of a light-emitting element or a wavelength conversion member with high light-emission intensity and excellent light-emission properties by using the QD-containing film 41 as a light-emitting layer or a wavelength conversion layer.

Next, results are presented of verifying the solution resistance of the QD-containing film 41 to polar solvents.

### Example 3

First, a precursor film was formed similarly to Example 2, thereafter subjected to ligand exchange similarly to Example 2, and thereafter rid of acetonitrile similarly to Example 2. Hence, a QD-containing film 41 containing red QDs and 2,2′-(ethylenedioxy)diethanethiol similarly to Embodiment 2 was formed.

Next, the thickness of the immediately post-film formation, QD-containing film 41 (i.e., after the acetonitrile removal) was measured using the same stylus profilometer as in Example 1.

Thereafter, a sufficient amount of ethanol as a rinse liquid was spread over the immediately post-film formation, QD-containing film 41, and 10 seconds later, the spread ethanol was applied by spin-coating at 2,000 rpm, washed (ethanol washing, rinsing), and thereafter heated at 100° C.

Thereafter, the thickness of the QD-containing film 41 after this ethanol washing (specifically, the QD-containing film 41 as obtained by heating and drying after the ethanol washing) was measured using the same stylus profilometer as in Example 1.

### COMPARATIVE EXAMPLE 4

The same procedures and measurements were carried out as in Example 3, except that no ligand exchange was performed. In other words, specifically, first, similarly to Comparative Example 3, a precursor film containing red QDs and octanethiol was formed as a comparative QD-containing film.

Next, the thickness of the comparative QD-containing film (precursor film) was measured using the same stylus profilometer as in Example 1.

Thereafter, a sufficient amount of ethanol as a rinse liquid was spread over the comparative QD-containing film, and 10 seconds later, the spread ethanol was applied by spin-coating at 2,000 rpm, washed (ethanol washing), and thereafter heated at 100° C.

Thereafter, the thickness of the comparative QD-containing film after the ethanol washing (specifically, the comparative QD-containing film as obtained by heating and drying after the ethanol washing) was measured using the same stylus profilometer as in Example 1.

FIG. 7 is a graph representing the thickness of the QD-containing films in accordance with Example 3 and Comparative Example 4 before and after being washed in ethanol.

Referring to FIG. 7, the comparative QD-containing film using non-polar monofunctional ligands having no polarity-imparting bonds as ligands has high solution resistance (alcohol resistance) to ethanol (polar solvent). However, as described above, the comparative QD-containing film using non-polar monofunctional ligands having no polarity-imparting bonds as ligands has low solution resistance to a non-polar solvent.

In contrast, it is understood from the results shown in FIG. 7 that the QD-containing film 41 using the ligands 43 in accordance with the present embodiment as ligands, despite having high solution resistance to a non-polar solvent as described above, also has high solution resistance (alcohol resistance) to ethanol (polar solvent).

As described in the foregoing, it is understood that the present embodiment can provide the QD-containing film 41 with high wettability to a polar solvent and high solution resistance to polar and non-polar solvents. In addition, it is understood that the use of the QD-containing film 41 enables providing a light-emitting device, such as a light-emitting element or a display device, that has excellent light-emission properties.

### Embodiment 2

As described above, the QD-containing film 41 can be suitably used, for example, as a light-emitting layer in a light-emitting element in a display device. The light-emitting element may be used, for example, as a light source in a display device or a light-emitting device such as a lighting device.

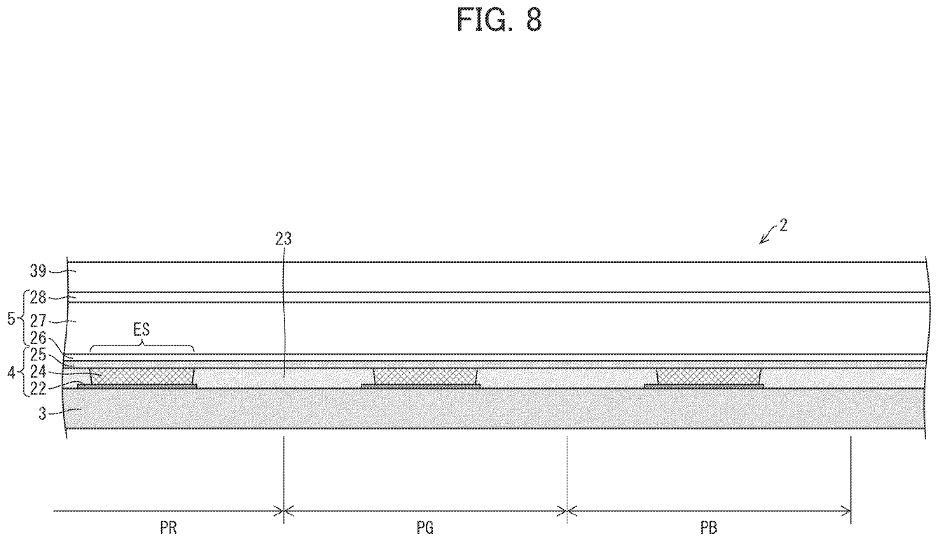

FIG. 8 is a schematic cross-sectional view of an exemplary structure of a major part of a display device 2 in accordance with the present embodiment.

The display device 2 includes a plurality of pixels. Each pixel includes a light-emitting element ES. The display device 2 has a structure including, as a substrate 3, an array substrate including a drive element layer and further including: a light-emitting element layer 4 including the plurality of light-emitting elements ES that emit light of different wavelengths; a sealing layer 5; and a functional film 39, all of which are stacked on the substrate 3 in this order. Note that note that in the present embodiment, the direction from the light-emitting elements ES toward the substrate 3 in the display device 2 is referred to as “downward,” and the direction from the substrate 3 toward the light-emitting elements ES in the display device 2 is referred to as “upward.” In addition, in the present embodiment, expressions like “layer A underlies/is below layer B” indicate that layer A is formed in an earlier process or step than layer B, and expressions like “layer A overlies/is on or above layer B” indicate that layer A is formed in a later process or step than layer B.

The display device 2 shown in FIG. 8 includes, as the pixels, red light-emitting, red pixels PR, green light-emitting, green pixels PG, and blue light-emitting, blue pixels PB. Between the pixels is there provided an insulating bank 23 that divides adjacent pixels as a pixel separation film.

The display device 2 includes, as the plurality of light-emitting elements ES that emit light of different wavelengths, red light-emitting elements that emit red light, green light-emitting elements that emit green light, and blue light-emitting elements that emit blue light. The red pixel PR includes a red light-emitting element as the light-emitting element ES. The green pixel PG includes a green light-emitting element as the light-emitting element ES. The blue pixel PB includes a blue light-emitting element as the light-emitting element ES.

The light-emitting element layer 4 has a structure including the plurality of light-emitting elements ES provided for the respective pixels and further including a stack of layers of these light-emitting elements ES on the substrate 3.

The substrate 3 functions as a support body for forming the layers of the light-emitting elements ES. The substrate 3 is an array substrate and includes, for example, a TFT (thin film transistor) layer as a drive element layer. The TFT layer includes, as a subpixel circuit, a drive circuit including TFTs or like drive elements for driving the light-emitting elements ES.

The light-emitting element layer 4, as an example, includes: a plurality of anodes 22 (first electrodes); a cathode 25 (second electrode); a functional layer 24 each provided between the anodes 22 and the cathode 25 and including at least a light-emitting layer; and the insulating bank 23 covering the edges of underlying electrodes (the anodes 22 in the example shown in FIG. 8) provided on the substrate 3.

Note that in the present embodiment, the layers between the anodes 22 and the cathode 25 are referred to collectively as the functional layer 24 (alternatively, the “active layers”). In addition, hereinafter, the light-emitting layer will be referred to as an “EML.”

Note that the functional layer 24 may be either a monolayered type including the EML alone or a multilayered type including an additional functional layer(s) other than the EML. Examples of the functional layer(s) other than the EML among these functional layers include a hole transport layer and an electron transport layer. Throughout the following description, the hole transport layer will be referred to as the “HTL,” and the electron transport layer as the “ETL.”

FIG. 8 shows an example where the underlying electrodes are the anodes 22 (pattern anodes), the overlying electrode is the cathode 25 (common cathode), and the light-emitting element layer 4 includes the anodes 22, the bank 23, the functional layer 24, and the cathode 25, all of which are stacked sequentially on the substrate 3. However, the present embodiment is by no means limited to this example. Alternatively, the underlying electrodes may be the cathode 25 (pattern cathode), the overlying electrode may be the anodes 22 (common anode), and the light-emitting element layer 4 may include the cathode 25, the bank 23, the functional layer 24, and the anodes 22, all of which are stacked sequentially on the substrate 3.

The bank 23 is used as an edge cover covering the edges of the patterned underlying electrodes and also serves as a pixel separation film. As an example, the underlying electrodes and the functional layer 24 are divided (pattern formed) for individual pixels by the bank 23. Hence, the light-emitting element layer 4 includes the light-emitting elements ES each corresponding to a different one of the pixel. The underlying electrodes for the light-emitting elements ES are electrically connected to the TFTs on the substrate 3. In contrast, the overlying electrode is provided commonly to all the pixels as a common electrode. Note that the structure of the light-emitting element ES will be described in more detail.

The light-emitting element layer 4 is covered by the sealing layer 5. The sealing layer 5 is transparent and includes, for example, a first inorganic sealing film 26, an organic sealing film 27, and a second inorganic sealing film 28, all of which are provided in this order when viewed from the underlying layer side (i.e., from the light-emitting element layer 4). It should be understood however that this is not the only possibility. Alternatively, the sealing layer 5 may be either a monolayered, inorganic sealing film or a stack body of five or more layers or organic and inorganic sealing films. In addition, the sealing layer 5 may be, for example, sealing glass. The light-emitting elements ES, sealed by the sealing layer 5, can be prevented from being permeated by, for example, water and oxygen.

The first inorganic sealing film 26 and the second inorganic sealing film 28 may be each formed of a silicon oxide film, a silicon nitride film, a silicon oxynitride film, or a stack of any of these films, each of which can be provided by, for example, CVD (chemical vapor deposition). The organic sealing film 27 is a transparent organic film that is thicker than the first inorganic sealing film 26 and the second inorganic sealing film 28 and may be made of, for example, a polyimide resin, an acrylic resin, or a like photosensitive resin that can be provided by printing or coating technology.

Note that the display device 2 may include, on the sealing layer 5, the functional film 39 which has, for example, at least one of the functions of an optical compensation function, a touch sensor function, and a protection function as shown in FIG. 8.

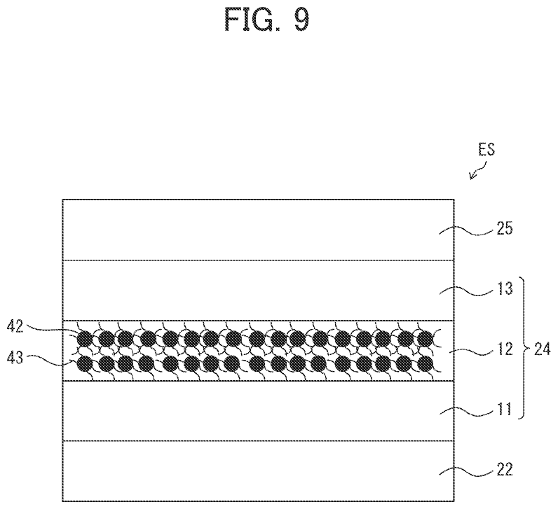

FIG. 9 is a schematic illustration of an example of the light-emitting element ES in accordance with the present embodiment.

Referring to FIG. 9, the light-emitting element ES has, as an example, a structure including a stack of an anode 22, an HTL 11, an EML 12, an ETL 13, and a cathode 25 in this order. The light-emitting element ES is an electroluminescent element that emits light when the EML 12 is placed under an applied voltage.

Note that in the display device 2, the substrate 3 functions as a support body for forming layers of the light-emitting element ES. In this manner, layers in the light-emitting element ES are formed on a substrate as a support body. Therefore, for example, to manufacture the light-emitting element ES as a stand-alone product, the light-emitting element ES may be referred to as a light-emitting element, including a substrate as a support body.

The anode 22 and the cathode 25 are configured such that a voltage is applied across the anode 22 and the cathode 25 when connected to a power supply (e.g., DC power supply) (not shown).

The anode 22 is an electrode that supplies holes to the EML 12 when a voltage is applied thereto. The cathode 25 is an electrode that supplies electrons to the EML 12 when a voltage is applied thereto.

Either one or both of the anode 22 and the cathode 25 is/are made of a light-transmitting material. Note that either one of the anode 22 and the cathode 25 may be made of a light-reflective material. The light-emitting element ES allows for light extraction through the electrode side made of a light-transmitting material.

Materials for the anode 22 and the cathode 25 are not limited in any particular manner and may be any materials similar to those materials that are known used as materials for an anode and a cathode of a light-emitting element.

The HTL 11 (first carrier transport layer) is a layer for transporting, to the EML 12, the holes supplied from the anode 22 and is provided adjacent to the EML 12 as shown in FIG. 9. Materials for the HTL 11 are not limited in any particular manner so long as the materials are a hole transport material and may be a publicly known hole transport material.

Examples of the hole transport material include p-type semiconductor materials such as metal oxides, Group II-VI compound semiconductors, Group III-V compound semiconductors, Group IV-IV compound semiconductors, amorphous semiconductors, and thiocyanate compounds, PEDOT (poly(3,4-ethylenedioxythiophene)), PEDOT-PSS (poly(3,4-ethylenedioxythiophene)-poly(styrene sulfonate)), and PVK (poly(N-vinyl carbazole)). Any one of these hole transport materials may be used alone. Alternatively, two or more of the hole transport materials may be used in the form of mixture where appropriate.

The ETL 13 (second carrier transport layer) is a layer for transporting, to the EML 12, the electrons supplied from the cathode 25 and is provided adjacent to the EML 12 as shown in FIG. 9. Materials for the ETL 13 are not limited in any particular manner so long as the materials are an electron transport material and may be a publicly known electron transport material.

Examples of the electron transport material include n-type semiconductor materials such as metal oxides, Group II-VI compound semiconductors, Group III-V compound semiconductors, Group IV-IV compound semiconductors, and amorphous semiconductors, 1,3,5-tris(1-phenyl-1H-benzimidazol-2-yl)benzene (TPBi), 3-(biphenyl-4-yl)-5-(4-tert-butylphenyl)-4-phenyl-4-H-1,2,4-triazole (TAZ), and bathophenanthroline (Bphen). Any one of these electron transport materials may be used alone. Alternatively, two or more of the electron transport materials may be used in the form of mixture where appropriate.

Note that the hole transport material is not limited in any particular manner so long as the hole transport material is a hole transport material. The hole transport material preferably contains either one or both of a metal oxide and a thiocyanate compound.

Likewise, the electron transport material, as described above, is not limited in any particular manner so long as the electron transport material is an electron transport material. The electron transport material may be an inorganic material such as an n-type semiconductor material or an organic material and preferably contains, for example, a metal oxide.

The metal oxide has high durability and reliability and can be easily provided by printing or coating technology. In addition, thiocyanate salt and other like thiocyanate compounds are inexpensive and easily available.

Examples of the metal oxides include zinc oxide (ZnO), titanium oxide (TiO₂), indium oxide (In₂O₃), tin oxide (SnO, SnO₂), and cerium oxide (CeO₂). Any one of these metal oxides may be used alone. Alternatively, two or more of the metal oxides may be used in the form of mixture where appropriate.

Note that the metal oxide is preferably metal oxide nanoparticles (i.e., a metal oxide or a mixed-crystal fine particles of a metal oxide) and is particularly preferably zinc oxide. Zn atom-containing semiconductor materials are capable of providing a light-emitting element with high strength, particularly, with high mechanical strength.

The particle diameter (diameter) of the nanoparticles such as metal oxide nanoparticles used as a carrier transport material such as a hole transport material or an electron transport material is, for example, from 1 to 15 nm. In addition, the overlapping layer number of nanoparticles in both the HTL 11 and the ETL 13 are, for example, from 1 to 10 layers.

The thiocyanate salt used as the hole transport material is, for example, thiocyanate salt such as copper thiocyanate.

The HTL 11 and the ETL 13 may have a known, publicly known thickness, which is, for example, from 1 to 150 nm.

The EML 12 is a layer that contains a light-emitting material and that emits light when the electrons transported from the anode 22 and the holes transported from the cathode 25 recombine.

The light-emitting element ES in accordance with the present embodiment is a quantum-dot light-emitting diode (QLED), and the EML 12 contains nanosized QDs 42 in accordance with the color of emitted light as a light-emitting material.

In the light-emitting element ES in accordance with the present embodiment, electrons and holes recombine in the EML 12 by the drive current between the cathode 25 and the anode 22, and the resultant excitons transition from the conduction band energy level (conduction band) to the valence band energy level (valence band) of the QDs 42, which produces light (fluorescent light or phosphorescent light).

As described above, the EML 12 in accordance with the present embodiment is a QD light-emitting layer containing QDs, and the display device 2 includes the QD-containing film 41 described in Embodiment 1 as the EML 12 in the light-emitting element ES. Therefore, the EML 12 contains the QDs 42 as QDs as described above and also contains the ligands 43 as ligands.

The EML 12, since containing the ligands 43 as ligands, has high wettability to a polar solvent and high solution resistance to polar and non-polar solvents. Therefore, for example, if a layer of a metal oxide such as ZnO is formed as the ETL 13 on the EML 12 or if the stacking order is reversed, significant effects are achieved, for example, when a layer of a metal acid compound such as NiO or a thiocyanate compound such as thiocyanate salt is, for example, formed as the HTL 11 on the EML 12.

### Specific Examples of Method of Manufacturing Light-Emitting Element ES

The following will discuss an exemplary method of manufacturing the light-emitting element ES by means of a specific example. It should be understood however that the specific example below is a mere example of a method of manufacturing the light-emitting element ES as described above and that the present embodiment is by no means limited to the example. Note that the following description will take as an example the light-emitting element ES being formed as a support body on a glass substrate.

In the method of manufacturing the light-emitting element ES, for example, first, an ITO (tin-doped indium oxide) is patterned as the anode 22 on the glass substrate as a support body.

Next, the glass substrate on which the ITO is patterned is spin-coated with PVK (poly(N-vinyl carbazole)) dissolved in CBZ (chlorobenzene) and then annealed to form, for example, a PVK film with a thickness of 20 nm as the HTL 11.

Next, a QD colloidal solution is dispensed dropwise on the PVK film, subjected to spin-coating at 3,000 rpm to form a film, thereafter, heated (annealed) at 110° C. for 15 minutes, to remove the solvent, and dried. Note that the QD colloidal solution is a QD colloidal solution prepared by dispersing, in hexane, the QDs 42 whose surface is modified with octanethiol to a ligand concentration of 20 wt % and a QD concentration of 20 mg/mL. The QDs 42 are red QDs that include a CdS core with a particle diameter of 1 nm and a ZnSe shell and that have a peak emission wavelength at 630 nm. Hence, a precursor film with a thickness of 20 nm is formed which will be the EML 12.

Next, a ligand solution prepared by dissolving, in acetonitrile, 0.1 mol/L 2,2′-(ethylenedioxy)diethanethiol (HSCH₂CH₂OCH₂CH₂OCH₂CH₂SH, ligands 43) is dispensed dropwise on the precursor film. Then, 10 seconds after the ligand solution is dispensed dropwise, the dropwise dispensed ligand solution is subjected to spin-coating at 2,000 rpm and thereafter heated (annealed) at 100° C. for 10 minutes. Thereafter, toluene is dispensed dropwise as a rinse liquid and subjected to spin-coating at 3,000 rpm to rinse off unnecessary ligands. Hence, the EML 12 is formed containing the QDs 42 and 2,2′-(ethylenedioxy)diethanethiol coordinated to the QDs 42.

Next, a colloidal solution of an ETL material prepared by dispersing 2.5 wt % ZnO nanoparticles in ethanol is dispensed dropwise on the EML 12 and subjected to spin-coating at 2,000 rpm. Then, after the film is formed of the colloidal solution of the ETL material, the film is heated (annealed) at 80° C. for 30 minutes to remove the solvent, and is dried. Hence, a ZnO-nanoparticle film with, for example, a thickness of 50 nm is formed as the ETL 13.

Next, an Al (aluminum) electrode with a thickness of 100 nm is formed as the cathode on the ZnO nanoparticles film by vacuum vapor deposition using a patterning mask.

Thereafter, for example, sealing glass coated with a UV (ultraviolet light) setting resin is placed so as to cover the active area for sealing. Hence, the light-emitting element ES can be formed.

Note that the specific example above has discussed, as an example, the QDs 42 being red QDs that emit red light. Alternatively, the QDs 42 may be, needless to say, green QDs that emit green light or blue QDs that emit blue light. In addition, materials, dimensions, and other various conditions other than the QDs 42 may be altered as appropriate on the basis of the description above.

In addition, the specific example has discussed, as an example, the light-emitting element ES being a bottom-emission light-emitting element through the substrate side of which the light emitted by the EML 12 is taken out. However, the light-emitting element ES may be a top-emission display device through the front surface (the top face, specifically, the sealing glass side) of which opposite the substrate the light is taken out.

In the present embodiment, as described above, the QD-containing film 41 containing the plurality of QDs 42 and the ligands 43 is formed as the EML 12. Therefore, as verified in Embodiment 1, even if, for example, a non-polar solvent like toluene is used as a rinse liquid as described above, the EML 12 dose not dissolve in the non-polar solvent. In addition, as verified in Embodiment 1, even if, for example, a colloidal solution containing a polar solvent like ether and a carrier transport material like an ETL material is applied on the EML 12 as described above, the EML 12 does not dissolves in the polar solvent. Besides, as verified in Embodiment 1, the EML 12 has high wettability to a polar solvent. Therefore, by applying on the EML 12, for example, a colloidal solution containing a polar solvent like ether and a carrier transport material like an ETL material as described above, the resultant light-emitting element ES has no gap at the interface between the EML 12 and the carrier transport layer, such as the ETL 13, which is an adjoining layer adjacent to the EML 12, is capable of restraining film detachment, and exhibits excellent light-emission properties.

As described in the foregoing, according to the present embodiment, it is possible to provide a light-emitting element and a display device that include, as the EML 12, the QD-containing film 41 with high wettability to a polar solvent and high solution resistance to polar and non-polar solvents and that exhibit excellent light-emission properties.

### Embodiment 3

The present embodiment will describe, as an example, the QD-containing film 41 being used, for example, as a wavelength conversion layer in a wavelength conversion sheet as a wavelength conversion member.

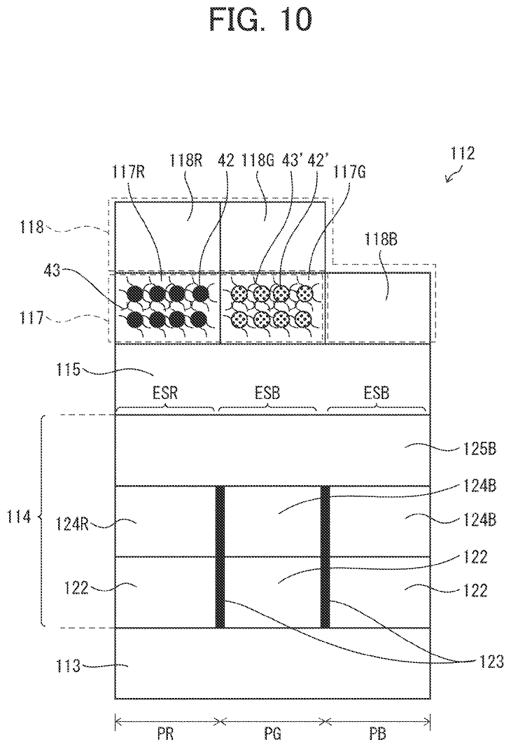

FIG. 10 is a schematic illustration of an exemplary structure of a major part of a display device 112 in accordance with the present embodiment.

The display device 112 in accordance with the present embodiment includes a plurality of pixels similarly to the display device 2 in accordance with Embodiment 2, and each pixel includes one light-emitting element. The display device 112 includes, as a substrate 113, an array substrate including a drive element layer and has a structure including: a light-emitting element layer 114 containing a plurality of light-emitting elements; a sealing layer 115; a wavelength conversion sheet 117 (wavelength conversion member); and a CF (color filter) sheet 118 (CF member), all of which are stacked on the substrate 113 in this order. Note that in an embodiment, the direction from the wavelength conversion sheet 117 toward the substrate 113 in the display device 112 is referred to as “downward,” and the direction from the substrate 113 toward the wavelength conversion sheet 117 in the display device 112 is referred to as “upward.” In addition, in the present embodiment, similarly to a previous embodiment, expressions like “layer A underlies/is below layer B” indicate that layer A is formed in an earlier process or step than layer B, and expressions like “layer A overlies/is on or above layer B” indicate that layer A is formed in a later process or step than layer B.

The display device 112 shown in FIG. 10, similarly to the display device 2 in accordance with Embodiment 2, includes red pixels PR, green pixels PG, and blue pixels PB as pixels. Between the pixels is there provided an insulating bank 123 that divides adjacent pixels as a pixel separation film.

In the display device 112, the red pixel PR includes, as a light-emitting element, a red light-emitting element ESR that emits red light. The green pixel PG and the blue pixel PB include, as a light-emitting element, a blue light-emitting element ESB that emits blue light.

The red light-emitting element ESR and the blue light-emitting element ESB are an electroluminescent element that emits light when the EML is placed under an applied voltage. The red light-emitting element ESR includes: an anode 122 (first electrode) in the red pixel PR; a cathode 125 (second electrode); and a functional layer 124R including a red light-emitting EML between the anode 122 and the cathode 125. The blue light-emitting element ESB includes: an anode 122 (first electrode) in the blue pixel PB; a cathode 125 (second electrode); and a functional layer 124B including a blue light-emitting EML between the anode 122 and the cathode 125.

The light-emitting element layer 114 includes the plurality of light-emitting elements for respective pixels and has a structure including a stack of the layers of these light-emitting elements (specifically, the red light-emitting elements ESR and the blue light-emitting elements ESB) on the substrate 113.

The substrate 113 functions as a support body for forming the layers of the light-emitting element. The substrate 113 is an array substrate and includes, for example, a TFT layer formed therein as a drive element layer. In the present embodiment, similarly to the previous embodiment, the TFT layer includes, as a subpixel circuit, a drive circuit including a drive element such as a TFT for driving the light-emitting element in each pixel.

The light-emitting element layer 114 includes, as an example: the plurality of anodes 122; the cathode 125; the functional layers (specifically, the functional layer 124R and the functional layer 124B) including at least the EML between the anodes 122 and the cathode 125; and an insulating bank 123 covering the edges of the underlying electrodes (the anodes 122 in the example shown in FIG. 8) on the substrate 113.

Note that FIG. 10 shows, as an example, the underlying electrodes being the anodes 122 (pattern anodes) and the overlying electrode being the cathode 125 (common cathode). However, the present embodiment is by no means limited to this example. Alternatively, the underlying electrodes may be the cathodes 125 (pattern cathodes), and the overlying electrode may be the anode 122 (common anode).

Although FIG. 10 shows layers in a simplified manner, the bank 123 has a similar structure to the structure of the bank 23. As described above, the bank 123 is used as an edge cover covering the edges of the patterned underlying electrodes and also functions as a pixel separation film. In the present embodiment, similarly to a previous embodiment, the underlying electrodes and the functional layers are, as an example, divided for individual pixels by the bank 123. Hence, the light-emitting element layer 114 includes the light-emitting elements each corresponding to a different one of the pixels. The underlying electrodes for the light-emitting elements are electrically connected to the TFTs on the substrate 113. In contrast, the overlying electrode is provided commonly to all the pixels as a common electrode.

The light-emitting element layer 114 is covered by the sealing layer 115. The anodes 122 are the same as the anodes 22 in the display device 2 in accordance with Embodiment 2. The cathode 125 is the same as the cathode 25 in the display device 2 in accordance with Embodiment 2. The sealing layer 115 is the same as the sealing layer 5 in the display device 2 in accordance with Embodiment 2.

The light-emitting element (the red light-emitting element ESR and the blue light-emitting element ESB) may be a QLED, an OLED (alternatively referred to as an organic light-emitting diode or an organic EL (electroluminescence) element), or an OLED (organic light-emitting diode) as shown in Embodiment 2. FIG. 10 describes an example where the light-emitting element is an OLED.

When the light-emitting element is an OLED as described here, holes and electrons recombine in the EML by the drive current between the anode 122 and the cathode 125, and the resultant excitons transition to the ground state, which produces light. Note that the same description applies to the light-emitting element being an inorganic EL.

When the light-emitting element is an OLED or an inorganic EL element, the EML may be made of, for example, either an organic light-emitting material or an inorganic light-emitting material, including a low molecular fluorescent (or phosphorescent) pigment or a metal complex.

The EML in the OLED or the inorganic EL element may be formed by, for example, vapor deposition using different light-emitting materials and different FMMs (fine metal masks) or inkjet printing with a light-emitting material.

The wavelength conversion sheet 117 shown in FIG. 10 includes a red wavelength conversion layer 117R and a green wavelength conversion layer 117G.

The red wavelength conversion layer 117R is provided corresponding to the red pixel PR. The green wavelength conversion layer 117G is provided corresponding to the green pixel PG.

The red wavelength conversion layer 117R and the green wavelength conversion layer 117G differ from the EML and emit light by PL (photoluminescence).

The red wavelength conversion layer 117R includes, as QDs 42, a plurality of red QDs that emit red light upon receiving the red light emitted by the red light-emitting element ESR as excitation light and also includes ligands 43 coordinated to this plurality of red QDs. The red wavelength conversion layer 117R converts the red light emitted by the red light-emitting element ESR to red light with a longer wavelength and emits the resultant red light.

The green wavelength conversion layer 117G includes, as QDs 42′, a plurality of green QDs that emit green light upon receiving the green light emitted by a green light-emitting element ESG as excitation light and also includes ligands 43′ coordinated to this plurality of green QDs. The green wavelength conversion layer 117G converts the blue light emitted by the blue light-emitting element ESB to green light and emits the resultant green light.

The red QDs and green QDs may be QDs similar to the QDs 42 described as an example in Embodiment 1. In addition, the ligands 43 in the red wavelength conversion layer 117R and the ligands 43′ in the green wavelength conversion layer 117G may be ligands similar to the ligands 43 described as an example in Embodiment 1.

Therefore, both the composition ratio of the red QDs and the ligands 43 ([red QDs]: [ligands 43]) in the red wavelength conversion layer 117R and the composition ratio of the green QDs and the ligands 43′ ([green QDs]: [ligands 43′]) in the green wavelength conversion layer 117G are preferably in the range of 2:0.25 to 2:6 and more preferably in the range of 2:1 to 2:4, in weight.

In addition, the red wavelength conversion layer 117R and the green wavelength conversion layer 117G may be formed, for example, by a method similar to the QD-containing film 41 shown in Embodiment 1.

Note that although the red wavelength conversion layer 117R is preferably made only of the red QDs and the ligands 43, the red wavelength conversion layer 117R may contain components other than the red QDs and the ligands 43 so long as the other components do not disrupt the ligand exchange and the effects of the present application and may have, for example, a structure where the red QDs to which the ligands 43 are coordinated are dispersed in a transparent resin such as an acrylic resin. In addition, although the green wavelength conversion layer 117G is preferably made only of the green QDs and the ligands 43′, the green wavelength conversion layer 117G may contain components other than the green QDs and the ligands 43′ so long as the other components do not disrupt the ligand exchange and the effects of the present application and may have, for example, a structure where the green QDs to which the ligands 43′ are coordinated are dispersed in a transparent resin such as an acrylic resin.

The CF sheet 118 includes a red CF layer 118R, a green CF layer 118G, and a blue CF layer 118B.

The red CF layer 118R selectively transmits red light. The red CF layer 118R has a high optical transmittance in the red wavelength range and a relatively low optical transmittance in the other wavelength ranges. The green CF layer 118G selectively transmits green light. The green CF layer 118G has a high optical transmittance in the green wavelength range and a relatively low optical transmittance in the other wavelength ranges. The blue CF layer 118B selectively transmits blue light. The blue CF layer 118B has a high optical transmittance in the blue wavelength range and a relatively low optical transmittance in the other wavelength ranges.

In the example shown in FIG. 10, the red CF layer 118R is disposed on the red wavelength conversion layer 117R in a manner corresponding to the red pixel PR to further narrow down the red light emission spectrum from the red wavelength conversion layer 117R. The green CF layer 118G is disposed on the green wavelength conversion layer 117G in a manner corresponding to the green pixel PG to further narrow down the green light emission spectrum from the green wavelength conversion layer 117G. The blue CF layer 118B is disposed in a manner corresponding to the blue pixel PB to further narrow down the blue light emission spectrum from the blue light-emitting element ESB disposed in the blue pixel PB.

The red CF layer 118R, the green CF layer 118G, and the blue CF layer 118B can be formed of any material and by any method and may be formed of a known, publicly known CF material and by a known, publicly known method. These CF layers may contain a pigment, a dye, or an inorganic material. Note that the CF sheet 118 may be provided only where needed and can be omitted.

In addition, the wavelength conversion sheet 117 and the CF sheet 118 may be provided integral to the light-emitting element as a part of the display device 112 as shown in FIG. 10 and may each be provided as an independent stand-alone product. In addition, the CF sheet 118 may be provided as an independent stand-alone product separately from the wavelength conversion sheet 117 and may be provided integral to the wavelength conversion sheet 117.

Therefore, the wavelength conversion sheet 117 may further include a transparent support body layer for supporting the red wavelength conversion layer 117R and the green wavelength conversion layer 117G and may further include an overcoat layer and/or spacers such as photospacers. Note that the present embodiment discusses an example where the wavelength conversion member is a wavelength conversion sheet. The wavelength conversion member may include, for example, a glass plate or a ceramic plate as a support body layer.

In addition, the wavelength conversion sheet 117 may further include a blue light transmissive layer (not shown) that transmits blue light emitted by the blue light-emitting element ESB. When the wavelength conversion sheet 117 includes a blue light transmissive layer, the blue light transmissive layer is provided in a manner corresponding to the blue pixel PB. Note that the blue light transmissive layer can be made of any material and is preferably made of a material that has a particularly high optical transmittance in at least the blue wavelength range (e.g., a transparent glass or a resin). Such a blue light transmissive layer may be formed by a method similar to the method of forming a light transmissive layer in a known wavelength conversion sheet.

Note that likewise, when the CF sheet 118 is provided as an independent stand-alone product separately from the wavelength conversion sheet 117, the CF sheet 118 may further include a transparent support body layer for supporting the red CF layer 118R, the green CF layer 118G, and the blue CF layer 118B and may further include an overcoat layer and/or spacers such as photospacers. In addition, the CF sheet 118 may include a light transmissive layer that transmits light of a particular color in place of some of the CF layers.

In any case, the present embodiment can provide a wavelength conversion member including a wavelength conversion layer that has high wettability to a polar solvent and high solution resistance to polar and non-polar solvents and that has excellent light-emission properties and also provide a display device including such a wavelength conversion member.

### Variation Examples

Note that the present embodiment has so far discussed an example where the light-emitting element layer 114 includes the red light-emitting element ESR and the blue light-emitting element ESB as light-emitting elements, these red and blue light-emitting elements ESR and ESB are OLEDs, and the wavelength conversion sheet 117 includes the red wavelength conversion layer 117R and the green wavelength conversion layer 117G. However, the display device in accordance with the present embodiment is by no means limited to this example. Alternatively, the light-emitting element may be, for example, an inorganic EL element as described earlier.

In addition, for example, the light-emitting element layer 114 may include only the blue light-emitting element ESB as a light-emitting element, and the wavelength conversion sheet 117 may include the red wavelength conversion layer 117R that converts the blue light emitted by the blue light-emitting element ESB to red light and the green wavelength conversion layer 117G that converts the blue light emitted by the blue light-emitting element ESB to green light. In such a case, the light-emitting element may be an OLED, an inorganic EL element, or a QLED.

The present disclosure is not limited to the description of the embodiments above and may be altered within the scope of the claims. Embodiments based on a proper combination of technical means disclosed in different embodiments are encompassed in the technical scope of the present disclosure. Furthermore, new technological features can be created by combining different technical means disclosed in the embodiments.

1. A quantum-dot-containing film comprising:
a plurality of quantum dots; and
a ligand, wherein
the ligand is a monomer that has: at least two coordinating functional groups of at least one species; and at least one polar bonding group of at least one species at a site other than a site at which the ligand is coordinated to the plurality of quantum dots.

2. The quantum-dot-containing film according to claim 1, wherein the ligand has a C₁-C₄, substituted or unsubstituted alkylene group bonded directly to the at least one polar bonding group.

3. The quantum-dot-containing film according to claim 1, wherein the ligand has, at each end of a main chain, the at least two coordinating functional groups that may be mutually identical or different.

4. The quantum-dot-containing film according to claim 1, wherein the ligand is a ligand of general formula (1) below,
R¹-A¹-A²(CH₂)ₙ—R² (1)
where R¹ and R² are each independently the at least two coordinating functional groups, A¹ is a substituted or unsubstituted —((CH₂)ₘ₁—X¹)ₘ₂— group, A² is a direct bond, a X² group, or a substituted or unsubstituted —((CH₂)ₘ₃—X²)ₘ₄— group, X¹ and X² are mutually different polar bonding groups, n, m1, and m3 are each independently an integer from 1 to 4, and m2 and m4 are each independently an integer from 1 to 10.

5. The quantum-dot-containing film according to claim 4, wherein
the A² is a direct bond, and
2≤m1×m2+n≤20.

6. The quantum-dot-containing film according to claim 5, wherein 3≤m1×m2+n≤10.

7. The quantum-dot-containing film according to claim 4, wherein
the A² is a —((CH₂)ₘ₃—X²)ₘ₄— group, and
2≤m1×m2+m3×m4+n≤20.

8. The quantum-dot-containing film according to claim 7, wherein 3≤m1×m2+m3×m4+n≤10.

9. The quantum-dot-containing film according to claim 1, wherein the at least two coordinating functional groups are each independently a thiol group, an amino group, a carboxyl group, a phosphonic group, a phosphine group, or a phosphine oxide group.

10. The quantum-dot-containing film according to claim 1, wherein
the plurality of quantum dots have a core-shell structure including a core and a shell,
the shell contains Zn, and
the at least two coordinating functional groups are thiol groups.

11. The quantum-dot-containing film according to claim 1, wherein the at least one polar bonding group is a polar bonding group selected from the group consisting of an ether bonding group, a sulfide bonding group, an imine bonding group, an ester bonding group, an amide bonding group, and a carbonyl group.

12. The quantum-dot-containing film according to claim 1, wherein the ligand is 2,2′-(ethylenedioxy)diethanethiol.

13. A light-emitting element comprising:
a first electrode;
a second electrode; and
a light-emitting layer between the first electrode and the second electrode, wherein
the light-emitting layer is the quantum-dot-containing film according to claim 1.

14. The light-emitting element according to claim 13, further comprising a carrier transport layer between the first electrode and the light-emitting layer and in contact with the light-emitting layer, wherein
the carrier transport layer contains either one or both of a metal oxide and a thiocyanate compound.

15. A display device comprising the light-emitting element according to claim 13.

16. A wavelength conversion member comprising the quantum-dot-containing film according to claim 1 as a wavelength conversion layer.

17. A display device comprising the wavelength conversion member according to claim 16.
